(19) United States
(12) Patent Application Publication
(10) Pub. No.: US 2022/0344388 A1
(43) Pub. Date: Oct. 27, 2022

(54) LIGHT-RECEIVING ELEMENT, DISTANCE MEASUREMENT MODULE, AND ELECTRONIC APPARATUS

(71) Applicant: SONY SEMICONDUCTOR SOLUTIONS CORPORATION, Kanagawa (JP)

(72) Inventors: Yoshiki EBIKO, Kanagawa (JP); Sozo YOKOGAWA, Kanagawa (JP); Junji NARUSE, Kanagawa (JP)

(73) Assignee: SONY SEMICONDUCTOR SOLUTIONS CORPORATION, Kanagawa (JP)

(21) Appl. No.: 17/760,736

(22) PCT Filed: Sep. 11, 2020
(86) PCT No.: PCT/JP2020/034436

§ 371 Date: Mar. 15, 2022

(30) Foreign Application Priority Data
Sep. 25, 2019 (JP) 2019-174416
Feb. 3, 2020 (JP) 2020-016233

(51) Int. Cl. H01L 27/146

(52) U.S. Cl. CPC H01L 27/14603; H01L 27/1461; H01L 27/14612; H01L 27/14623; H01L 27/14629; H01L 27/1463; H01L 27/1464

(57) ABSTRACT

There is provided a light-receiving element including: an on-chip lens; an interconnection layer; and a semiconductor layer arranged between the on-chip lens and the interconnection layer, the semiconductor layer including a photodiode, an interpixel trench portion engraved up to at least a part in a depth direction of the semiconductor layer at a boundary portion of an adjacent pixel, and an in-pixel trench portion engraved at a prescribed depth from a front surface or a rear surface of the semiconductor layer at a position overlapping a part of the photodiode in a plan view.

### TECHNICAL FIELD

The present technology relates to a light-receiving element, a distance measurement module, and an electronic apparatus and, in particular, to a light-receiving element, a distance measurement module, and an electronic apparatus that make it possible to reduce the leakage of incident light into an adjacent pixel.

### CROSS REFERENCE TO RELATED APPLICATIONS

This application claims the benefit of Japanese Priority Patent Application JP 2019-174416 filed Sep. 25, 2019, and Japanese Priority Patent Application JP 2020-016233 filed Feb. 3, 2020, the entire contents of each of which are incorporated herein by reference.

### BACKGROUND ART

Conventionally, distance measurement systems using an indirect ToF (Time of Flight) method have been known. In such distance measurement systems, it is necessary to have a sensor capable of distributing signal charges, which are obtained by receiving light reflected when active light irradiated using a LED (Light Emitting Diode) or a laser at a certain phase is applied to a target object, to different regions at high a speed.

In view of this, there has been proposed a technology in which a voltage is directly applied to the substrate of a sensor to generate a current inside the substrate so that a wide region inside the substrate can be modulated at a high speed.

### CITATION LIST

### Patent Literature

PTL 1: Japanese Patent Application Laid-open No. 2011-86904

### SUMMARY OF INVENTION

### Technical Problem

As the light source of a light-receiving element used in the indirect ToF method, near-infrared rays having a wavelength of about 940 nm are used in many cases. Since silicon serving as a semiconductor layer has a low absorption coefficient and low quantum efficiency with respect to the near-infrared rays, a structure in which a light path length is extended to increase the quantum efficiency is assumed. However, there is a concern about the leakage of incident light into an adjacent pixel.

The present technology has been made in view of the above circumstances and has an object of reducing the leakage of incident light into an adjacent pixel.

### Solution to Problem

A light-receiving element according to a first embodiment of the present technology includes:

an on-chip lens;

an interconnection layer; and

a semiconductor layer arranged between the on-chip lens and the interconnection layer,

the semiconductor layer including

a photodiode,

an interpixel trench portion engraved up to at least a part in a depth direction of the semiconductor layer at a boundary portion of an adjacent pixel, and

an in-pixel trench portion engraved at a prescribed depth from a front surface or a rear surface of the semiconductor layer at a position overlapping a part of the photodiode in a plan view.

A distance measurement module according to a second embodiment of the present technology includes:

a prescribed light-emitting source; and

a light-receiving element,

the light-receiving element including

an on-chip lens,

an interconnection layer, and

a semiconductor layer arranged between the on-chip lens and the interconnection layer,

the semiconductor layer including

a photodiode,

an interpixel trench portion engraved up to at least a part in a depth direction of the semiconductor layer at a boundary portion of an adjacent pixel, and

an in-pixel trench portion engraved at a prescribed depth from a front surface or a rear surface of the semiconductor layer at a position overlapping a part of the photodiode in a plan view.

An electronic apparatus according to a third embodiment of the present technology includes:

a distance measurement module including

a prescribed light-emitting source and

a light-receiving element,

the light-receiving element including

an on-chip lens,
an interconnection layer, and
a semiconductor layer arranged between the on-chip lens and the interconnection layer, the semiconductor layer including
a photodiode,
an interpixel trench portion engraved up to at least a part in a depth direction of the semiconductor layer at a boundary portion of an adjacent pixel, and
an in-pixel trench portion engraved at a prescribed depth from a front surface or a rear surface of the semiconductor layer at a position overlapping a part of the photodiode in a plan view.

In the first to third embodiments of the present technology, a light-receiving element is provided with an on-chip lens, an interconnection layer, and a semiconductor layer arranged between the on-chip lens and the interconnection layer, and the semiconductor layer is provided with a photodiode, an interpixel trench portion engraved up to at least a part in a depth direction of the semiconductor layer at a boundary portion of an adjacent pixel, and an in-pixel trench portion engraved at a prescribed depth from a front surface or a rear surface of the semiconductor layer at a position overlapping a part of the photodiode in a plan view.

The light-receiving element, the distance measurement module, and the electronic apparatus may be independent equipment, or may be modules embedded in other equipment.

### BRIEF DESCRIPTION OF DRAWINGS

FIG. 1 is a block diagram showing a schematic configuration example of a light-receiving element to which the present technology is applied.

FIG. 2 is a cross-sectional view showing a first configuration example of a pixel.

FIGS. 3A and 3B are plan views of an interpixel trench portion and an in-pixel trench portion.

FIG. 4 is a diagram showing a circuit configuration example of the pixel of FIG. 2.

FIG. 5 is a plan view showing an arrangement example of a pixel circuit of FIG. 4.

FIG. 6 is a diagram showing another circuit configuration example of the pixel of FIG. 2.

FIG. 7 is a plan view showing an arrangement example of a pixel circuit of FIG. 6.

FIG. 8 is a cross-sectional view showing a second configuration example of the pixel.

FIG. 9 is a cross-sectional view showing a third configuration example of the pixel.

FIG. 10 is a cross-sectional view showing a modified example of the third configuration example of the pixel.

FIG. 11 is a plan view of the interpixel trench portion and the in-pixel trench portion of FIG. 10.

FIG. 12 is a plan view showing an arrangement example of the in-pixel trench portion according to the arrangement of pixel transistors.

FIG. 13 is a cross-sectional view showing a fourth configuration example of the pixel.

FIG. 14 is a cross-sectional view showing a fifth configuration example of the pixel.

FIG. 15 is a plan view showing the arrangement of on-chip lenses of the pixel according to the fifth configuration example.

FIG. 16 is a cross-sectional view showing a sixth configuration example of the pixel.

FIG. 17 is a plan view of the interpixel trench portion and the in-pixel trench portion in the sixth configuration example.

FIG. 18 is a cross-sectional view showing a seventh configuration example of the pixel.

FIG. 19 is a diagram showing a circuit configuration example of the pixel in a case in which a light-receiving element includes an IR imaging sensor.

FIG. 20 is a cross-sectional view showing a first configuration example of the pixel in a case in which the light-receiving element is configured as an IR imaging sensor.

FIG. 21 is a cross-sectional view showing a second configuration example of the pixel in a case in which the light-receiving element includes an IR imaging sensor.

FIG. 22 is a plan view of the pixel that shows the planar arrangement of a diffusion film of FIG. 21.

FIG. 23 is a cross-sectional view showing a third configuration example of the pixel in a case in which the light-receiving element includes an IR imaging sensor.

FIG. 24 is a plan view of the pixel that shows the planar arrangement of the diffusion film of FIG. 23.

FIG. 25 is a cross-sectional view showing a fourth configuration example of the pixel in a case in which the light-receiving element includes an IR imaging sensor.

FIGS. 26A and 26B are plan views of the in-pixel trench portion of FIG. 25.

FIG. 27 is a plan view showing a modified example of the diffusion film.

FIG. 28 is a diagram showing a circuit configuration example in a case in which the pixel is a SPAD pixel.

FIG. 29 is a diagram describing the operation of the SPAD pixel.

FIG. 30 is a cross-sectional view showing a first configuration example in a case in which the pixel is a SPAD pixel.

FIG. 31 is a plan view of the SPAD pixel that shows the planar arrangement of a diffusion film.

FIG. 32 is a cross-sectional view showing a second configuration example in a case in which the pixel is a SPAD pixel.

FIG. 33 is a cross-sectional view showing a third configuration example in a case in which the pixel is a SPAD pixel.

FIG. 34 is a diagram showing a circuit configuration example in a case in which the pixel is a CAPD pixel.

FIG. 35 is a cross-sectional view in a case in which the pixel is a CAPD pixel.

FIG. 36 is a plan view showing the arrangement of signal extraction units and a diffusion film in a case in which the pixel is a CAPD pixel.

FIGS. 37A to 37C are diagrams each showing a pixel arrangement example in a case in which the light-receiving element includes an RGBIR imaging sensor.

FIG. 38 is a block diagram showing a configuration example of a distance measurement module to which the present technology is applied.

FIG. 39 is a block diagram showing a configuration example of a smart phone as an electronic apparatus to which the present technology is applied.

FIG. 40 is a block diagram depicting an example of schematic configuration of a vehicle control system.

FIG. 41 is a diagram of assistance in explaining an example of installation positions of an outside-vehicle information detecting section and an imaging section.

### DESCRIPTION OF EMBODIMENTS

Hereinafter, modes (called embodiments below) for carrying out the present technology will be described. Note that the description will be given in the following order.

1. Configuration Example of Light-Receiving Element

2. Cross-Sectional View Related to First Configuration Example of Pixel

3. Circuit Configuration Example of Pixel

4. Plan View of Pixel

5. Another Circuit Configuration Example of Pixel

6. Plan View of Pixel

7. Cross-Sectional View Related to Second Configuration Example of Pixel

8. Cross-Sectional View Related to Third Configuration Example of Pixel

9. Cross-Sectional View Related to Fourth Configuration Example of Pixel

10. Cross-Sectional View Related to Fifth Configuration Example of Pixel

11. Cross-Sectional View Related to Sixth Configuration Example of Pixel

12. Cross-Sectional View Related to Seventh Configuration Example of Pixel

13. First Configuration Example of IR Imaging Sensor

14. Second Configuration Example of IR Imaging Sensor

15. Third Configuration Example of IR Imaging Sensor

16. Fourth Configuration Example of IR Imaging Sensor

17. First Configuration Example of SPAD Pixel

18. Second Configuration Example of SPAD Pixel

19. Third Configuration Example of SPAD Pixel

20. Configuration Example of CAPD Pixel

21. Configuration Example of RGBIR Imaging Sensor

22. Configuration Example of Distance Measurement Module

23. Configuration Example of Electronic Apparatus

24. Application Example to Moving Body

Note that the same or similar portions will be denoted by the same or similar reference symbols in drawings that will be referred to in the following description. However, the drawings are schematically shown, and the relationships between thicknesses and plane sizes, the ratios of the thicknesses of respective layers, or the like are different from actual ones. Further, even among the drawings, some portions may have size relationships or ratios different from each other.

Further, the definition of a direction such as an upper side and a lower side in the following description is given only for the convenience of illustration and does not intend to limit the technical idea of the present disclosure. For example, an upper side and a lower side are converted into a right side and a left side, respectively, when a target object is rotated by 90° for observation, and turned upside down when the target object is rotated by 180° for observation.

<1. Configuration Example of Light-Receiving Element>

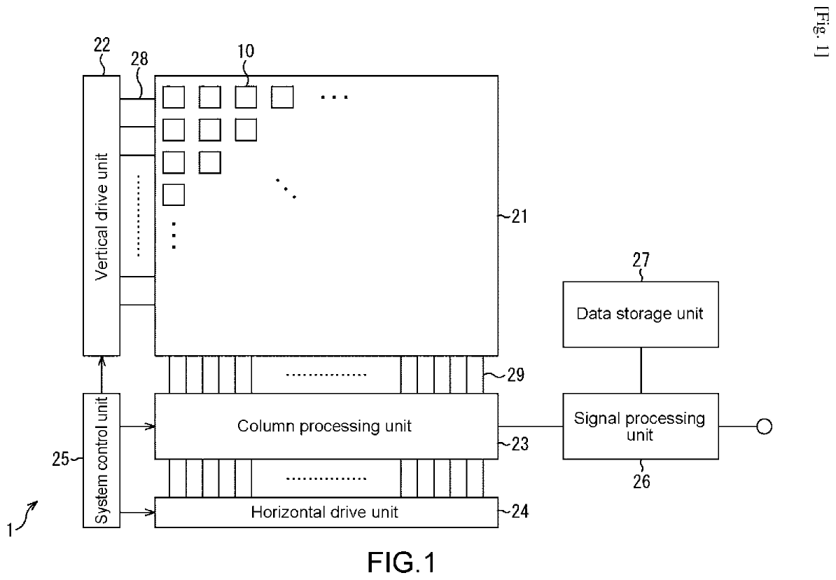

FIG. 1 is a block diagram showing a schematic configuration example of a light-receiving element to which the present technology is applied.

A light-receiving element 1 shown in FIG. 1 is a ToF sensor that outputs distance measurement information based on an indirect ToF method.

The light-receiving element 1 receives light (reflected light) reflected when light (irradiation light) irradiated from a prescribed light source is applied to an object, and then outputs a depth image in which information on a distance to the object is stored as a depth value. Note that the irradiation light irradiated from the light source is, for example, infrared light having a wavelength of 780 nm to 1000 nm and is pulsed light repeatedly turned on/off at a prescribed cycle.

The light-receiving element 1 includes a pixel array unit 21 that is formed on a semiconductor substrate (not illustrated), and a peripheral circuit unit that is integrated on the same semiconductor substrate as in the pixel array unit 21. For example, the peripheral circuit unit includes a vertical drive unit 22, a column processing unit 23, a horizontal drive unit 24, a system control unit 25, and the like.

A signal processing unit 26 and a data storage unit 27 are also provided in the light-receiving element 1. Note that the signal processing unit 26 and the data storage unit 27 may be mounted on the same substrate as in the light-receiving element 1, or may be disposed on a substrate in a module different from the light-receiving element 1.

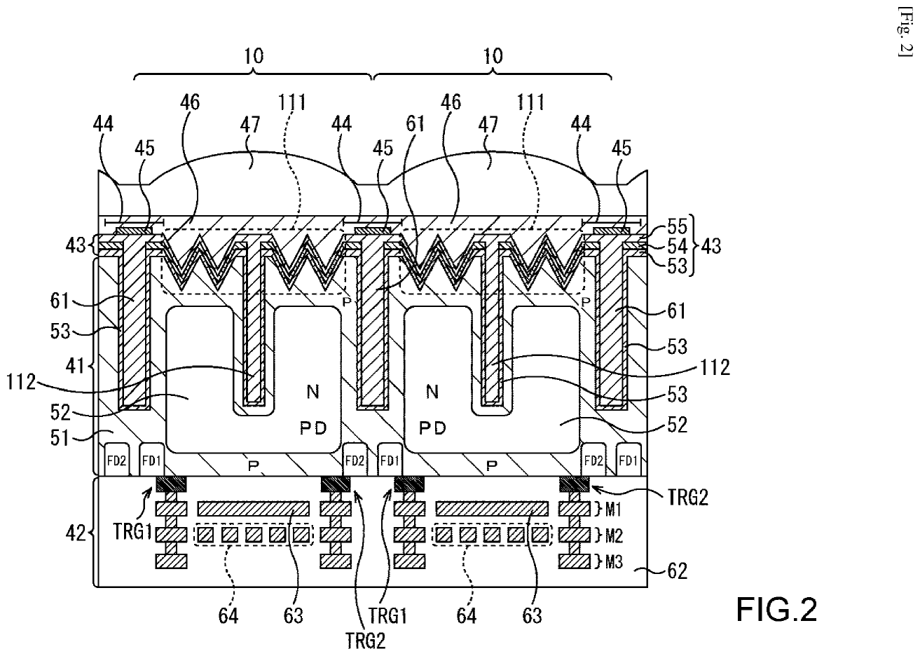

The pixel array unit 21 generates charges corresponding to the amount of light received, and has a configuration in which pixels 10 which output signals corresponding to the charges are two-dimensionally arranged in a matrix shape in a row direction and a column direction. That is, the pixel array unit 21 includes multiple pixels 10 which photoelectrically convert incident light and output signals corresponding to charges obtained as a result of the photoelectric conversion. Here, the row direction represents an arrangement direction of the pixels 10 in a horizontal direction, and the column direction represents an arrangement direction of the pixels 10 in a vertical direction. The row direction is the horizontal direction in the drawing and the column direction is the vertical direction in the drawing. Details of the pixels 10 will be described below with reference to FIG. 2 and subsequent drawings.

In the pixel array unit 21, with respect to a matrix-shaped pixel arrangement, a pixel drive line 28 is wired in a row direction for every pixel row, and two vertical signal lines 29 are wired along a column direction for every pixel column. The pixel drive line 28 transfers a drive signal for performing driving when reading out a signal from the pixel 10. Note that in FIG. 1, the pixel drive line 28 is illustrated as one interconnection, but there is no limitation to the one piece. One end of the pixel drive line 28 is connected to an output end corresponding to each row of the vertical drive unit 22.

The vertical drive unit 22 is constituted by a shift register, an address decoder, or the like, and drives the pixels 10 of the pixel array unit 21 simultaneously or in a row unit. That is, the vertical drive unit 22 constitutes a drive unit that controls an operation of each of the pixels 10 of the pixel array unit 21 in combination with the system control unit 25 that controls the vertical drive unit 22.

A detection signal that is output from each of the pixels 10 in a pixel row in correspondence with drive control by the vertical drive unit 22 is input to the column processing unit 23 through the vertical signal line 29. The column processing unit 23 performs predetermined signal processing with respect to the detection signal that is output from the pixel 10 through the vertical signal line 29, and temporarily stores the detection signal after signal processing. Specifically, the column processing unit 23 performs noise removal processing, analog to digital (AD) conversion processing, or the like as the signal processing.

The horizontal drive unit 24 is constituted by a shift register, an address decoder, or the like, and sequentially selects a unit circuit corresponding to a pixel column of the column processing unit 23. A detection signal that is subjected to signal processing for every unit circuit in the column processing unit 23 is sequentially output to the signal processing unit 26 due to selective scanning by the horizontal drive unit 24.

The system control unit 25 is constituted by a timing generator that generates various timing signals, or the like, and performs drive control of the vertical drive unit 22, the column processing unit 23, the horizontal drive unit 24, or the like on the basis of the various timing signals generated in the timing generator.

The signal processing unit 26 has at least a computation processing function, and performs various kinds of signal processing such as computation processing on the basis of the detection signal output from the column processing unit 23. At the time of the signal processing in the signal processing unit 26, the data storage unit 27 temporarily stores data necessary for the processing.

The light-receiving element 1 configured as described above outputs a depth image in which information on a distance to an object is stored in a pixel value as a depth value.

<2. Cross-Sectional View Related to First Configuration Example of Pixel>

FIG. 2 is a cross-sectional view showing a first configuration example of a pixel 10 arranged in the pixel array unit 21.

The light-receiving element 1 includes a semiconductor substrate 41 that is a semiconductor layer and a multilayer interconnection layer 42 formed on its front surface side (lower side in the figure).

The semiconductor substrate 41 is made of, for example, silicon (Si) and formed to have a thickness of, for example, 1 to 6 μm. In the semiconductor substrate 41, an N-type (second conductivity type) semiconductor region 52 is formed in a P-type (first conductivity type) semiconductor region 51 on a pixel-by-pixel basis, whereby a photodiode PD is formed on a pixel-by-pixel basis. The P-type semiconductor region 51 provided at both front and rear surfaces of the semiconductor substrate 41 serves also as a hole charge accumulation region that reduces a dark current.

The upper surface of the semiconductor substrate 41 that corresponds to an upper side in FIG. 2 is the rear surface of the semiconductor substrate 41 and becomes a light incident surface on which light is incident. On the upper surface on the rear surface side of the semiconductor substrate 41, an antireflection film 43 is formed.

The antireflection film 43 has, for example, a lamination structure in which a fixed charge film and an oxide film are laminated with each other, and an insulating thin film having a high dielectric constant (High-k) based on an ALD (Atomic Layer Deposition) method can be, for example, used. Specifically, hafnium oxide (HfO₂), aluminum oxide (Al₂O₃), titanium oxide (TiO₂), STO (Strontium Titan Oxide), or the like can be used. In the example of FIG. 2, the antireflection film 43 includes the hafnium oxide film 53, the aluminum oxide film 54, and the silicon oxide film 55 laminated with each other.

On the rear surface of the semiconductor substrate 41 and over the forming region of the photodiode PD, a moth-eye structure portion 111 having periodic fine irregularities is formed. Further, the antireflection film 43 formed on the upper surface of the moth-eye structure portion 111 is also formed to have a moth-eye structure so as to correspond to the moth-eye structure portion 111 of the semiconductor substrate 41.

The moth-eye structure portion 111 of the semiconductor substrate 41 has, for example, a configuration in which a plurality of quadrangular pyramid regions having substantially the same shape and substantially the same size is regularly provided (in a lattice-shaped pattern).

The moth-eye structure portion 111 is formed into, for example, a reverse pyramid structure in which a plurality of quadrangular pyramid regions having apexes on the side of the photodiode PD is arranged so as to be regularly placed in line.

Alternatively, the moth-eye structure portion 111 may have a forward pyramid structure in which a plurality of quadrangular pyramid regions having apexes on the side of an on-chip lens 47 is arranged so as to be regularly placed in line. The plurality of quadrangular pyramids may not be regularly placed in line but their sizes and arrangements may be randomly set. Further, the respective recessed portions or respective protrusion portions of the respective quadrangular pyramids of the moth-eye structure portion 111 may have a curvature to a certain extent and have a rounded shape. The moth-eye structure portion 111 may only have a structure in which the irregularity structures are periodically or randomly repeated, and the recessed portions or the protrusion portions have any shape.

The moth-eye structure portion 111 is formed on the light incident surface of the semiconductor substrate 41 as a diffraction structure that diffracts incident light as described above, whereby it is possible to reduce a sudden change in refractive index at the interface of the substrate and reduce influence caused by reflected light.

On the upper surface of the antireflection film 43 and at a boundary portion 44 of an adjacent pixel 10 (also called a pixel boundary portion 44 below), an interpixel light-shielding film 45 that prevents incident light from being incident on the adjacent pixel is formed. The material of the interpixel light-shielding film 45 may only be a material that shields light, and a metal material such as tungsten (W), aluminum (Al), and copper (Cu) can be, for example, used.

On the upper surface of the antireflection film 43 and on the upper surface of the interpixel light-shielding film 45, a flattening film 46 is formed by, for example, an insulating film such as silicon oxide (SiO₂), silicon nitride (SiN), and silicon oxynitride (SiON) or an organic material such as a resin.

Further, on the upper surface of the flattening film 46, the on-chip lens 47 is formed on a pixel-by-pixel basis. The on-chip lens 47 is made of, for example, a resin material such as a styrene resin, an acrylic resin, a styrene-acryl copolymerization resin, and a siloxane resin. Light condensed by the on-chip lens 47 is efficiently incident on the photodiode PD.

Further, at the pixel boundary portion 44 on the rear surface side of the semiconductor substrate 41, an interpixel trench portion 61 is formed. The interpixel trench portion 61 is formed to be engraved up to a prescribed depth in a substrate depth direction from the rear surface side (on the side of the on-chip lens 47) of the semiconductor substrate 41 and separates adjacent pixels from each other. An outer peripheral part including the bottom surface and the lateral wall of the interpixel trench portion 61 is covered with the hafnium oxide film 53 that is a part of the antireflection film 43. The interpixel trench portion 61 prevents incident light from penetrating an adjacent pixel 10 while confining the same inside the own pixel, and prevents the leakage of incident light from the adjacent pixel 10.

Further, at the central part of the moth-eye structure portion 11, an in-pixel trench portion 112 is formed. The in-pixel trench portion 112 is formed up to a prescribed depth at which the in-pixel trench portion 112 does not penetrate the photodiode PD in the substrate depth direction from the rear surface side of the semiconductor substrate 41, and separates a part of the N-type semiconductor region 52. An outer peripheral part including the bottom surface and the lateral wall of the in-pixel trench portion 112 is covered with the hafnium oxide film 53 that is a part of the antireflection film 43. The in-pixel trench portion 112 causes incident light to be reflected and confined inside the own pixel to prevent the incident light from penetrating an adjacent pixel 10.

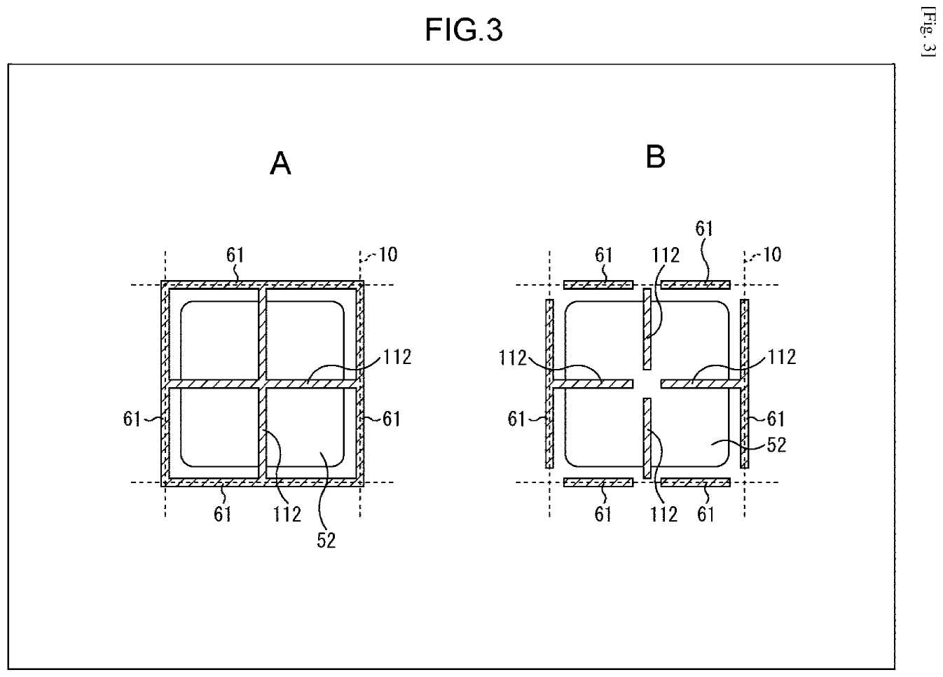

FIGS. 3A and 3B are plan views of the interpixel trench portion 61 and the in-pixel trench portion 112 when seen from the side of the on-chip lens 47.

As shown in FIG. 3A, the interpixel trench portion 61 is formed at the boundary portion between the pixels 10 two-dimensionally arranged in a matrix-shaped pattern. On the other hand, the in-pixel trench portion 112 is formed into a cross shape so that the rectangular planar region of the pixel 10 is halved in each of a row direction and a column direction to be divided into four regions. The in-pixel trench portion 112 is positioned so as overlap a part of the region of the photodiode PD in a plan view but is formed at a depth at which the in-pixel trench portion 112 does not penetrate the photodiode PD as is clear from the cross-sectional view of FIG. 2. Therefore, the region of the photodiode PD remains intact.

As shown in FIG. 3B, one of or both the interpixel trench portion 61 and the in-pixel trench portion 112 may not be formed at their intersections at which the trench portions cross each other.

Referring back to FIG. 2, the interpixel trench portion 61 and the in-pixel trench portion 112 are formed in such a manner that the silicon oxide film 55 that is the material of the uppermost layer of the antireflection film 43 is embedded in a trench (groove) engraved from the rear surface side. Thus, the silicon oxide film 55 that is the uppermost layer of the antireflection film 43, the interpixel trench portion 61, and the in-pixel trench portion 112 can be simultaneously formed, and the interpixel trench portion 61 and the in-pixel trench portion 112 are made of the same material.

However, the interpixel trench portion 61 and the in-pixel trench portion 112 may be made of different materials. For example, one of the interpixel trench portion 61 and the in-pixel trench portion 112 can be made of a metal material such as tungsten (W), aluminum (Al), titanium (Ti), and titanium nitride (TiN) or polysilicon, and the other thereof can be made of silicon oxide.

Note that the interpixel trench portion 61 and the in-pixel trench portion 112 have substantially the same depth in FIG. 2 but can have different depths in the thickness direction of the substrate. If the interpixel trench portion 61 is formed to have a depth deeper than that of the in-pixel trench portion 112, the penetration of incident light into an adjacent pixel can be prevented.

Meanwhile, on the front surface side of the semiconductor substrate 41 on which the multilayer interconnection layer 42 is formed, two transfer transistors TRG1 and TRG2 are formed with respect to one photodiode PD formed in each pixel 10. Further, on the front surface side of the semiconductor substrate 41, floating diffusion regions FD1 and FD2 serving as charge accumulation units that temporarily retain charges transferred from the photodiode PD are formed by concentrated N-type semiconductor regions (N-type diffusion regions).

The multilayer interconnection layer 42 includes a plurality of metal films M and an interlayer insulating film 62 between the metal films M. FIG. 2 shows an example in which the multilayer interconnection layer 42 includes the three layers of a first metal film M1 to a third metal film M3.

In a region positioned under the forming region of the photodiode PD, i.e., a region at least partially overlapping the forming region of the photodiode PD in the plan view of the first metal film M1 closest to the semiconductor substrate 41 among the plurality of metal films M of the multilayer interconnection layer 42, a metal interconnection such as copper and aluminum is formed as a light-shielding member 63.

The light-shielding member 63 shields infrared light, which has been incident on the semiconductor substrate 41 from the light incident surface via the on-chip lens 47 and has passed through the semiconductor substrate 41 without being photoelectrically converted inside the semiconductor substrate 41, with the first metal film M1 closest to the semiconductor substrate 41 and prevents the infrared light from passing through the second metal film M2 and the third metal film M3 positioned under the first metal film M1. With the light-shielding function, it is possible to prevent infrared light, which has passed through the semiconductor substrate 41 without being photoelectrically converted inside the semiconductor substrate 41, from being scattered with the metal films M positioned under the first metal film M1 and incident on an adjacent pixel. Thus, it is possible to prevent the false detection of light by an adjacent pixel.

Further, the light-shielding member 63 also has the function of causing infrared light, which has been incident on the semiconductor substrate 41 from the light incident surface via the on-chip lens 47 and has passed through the semiconductor substrate 41 without being photoelectrically converted inside the semiconductor substrate 41, to be reflected by the light-shielding member 63 and incident on the semiconductor substrate 41 again. Accordingly, it can be said that the light-shielding member 63 serves also as a reflection member. With the reflecting function, it is possible to further increase the amount of infrared light photoelectrically converted inside the semiconductor substrate 41 and improve quantum efficiency (QE), that is, the sensitivity of the pixel 10 with respect to the infrared light.

Note that the light-shielding member 63 may be structured to reflect or shield light with polysilicon, an oxide film, or the like, besides a metal material.

Further, the light-shielding member 63 may not include one layer of the metal film M but may include a plurality of metal films M with, for example, the first metal film M1 and the second metal film M2 formed into a lattice shape.

By, for example, the formation of the pattern of a comb teeth shape in the second metal film M2 that is a prescribed metal film M among the plurality of metal films M of the multilayer interconnection layer 42, an interconnection capacity 64 is formed. The light-shielding member 63 and the interconnection capacity 64 may be formed in the same layer (metal layer M). However, when the light-shielding member 63 and the interconnection capacity 64 are formed in different layers, the interconnection capacity 64 is formed in a layer farther from the semiconductor substrate 41 than the light-shielding member 63. In other words, the light-shielding member 63 is formed to be closer to the semiconductor substrate 41 than the interconnection capacity 64.

As described above, the light-receiving element 1 has a back-illuminated type structure in which the semiconductor substrate 41 that is a semiconductor layer is arranged between the on-chip lens 47 and the multilayer interconnection layer 42 and which causes incident light to be incident on the photodiode PD from the rear surface side on which the on-chip lens 47 is formed.

Further, the pixel 10 includes the two transfer transistors TRG1 and TRG2 with respect to the photodiode PD provided in each pixel and is configured to be capable of distributing charges (electrons) generated by being photoelectrically converted by the photodiode PD to the floating diffusion region FD1 or FD2.

In addition, the pixel 10 according to the first configuration example has the interpixel trench portion 61 at the pixel boundary portion 44 and the in-pixel trench portion 112 at the central part of the pixel to prevent incident light from penetrating an adjacent pixel 10 while confining the same inside the own pixel and prevent the leakage of incident light from the adjacent pixel 10. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

With the above configurations, it is possible to further increase the amount of infrared light photoelectrically converted inside the semiconductor substrate 41 and improve quantum efficiency (QE), that is, sensitivity to the infrared light in the pixel 10 according to the first configuration example.

<3. Circuit Configuration Example of Pixel>

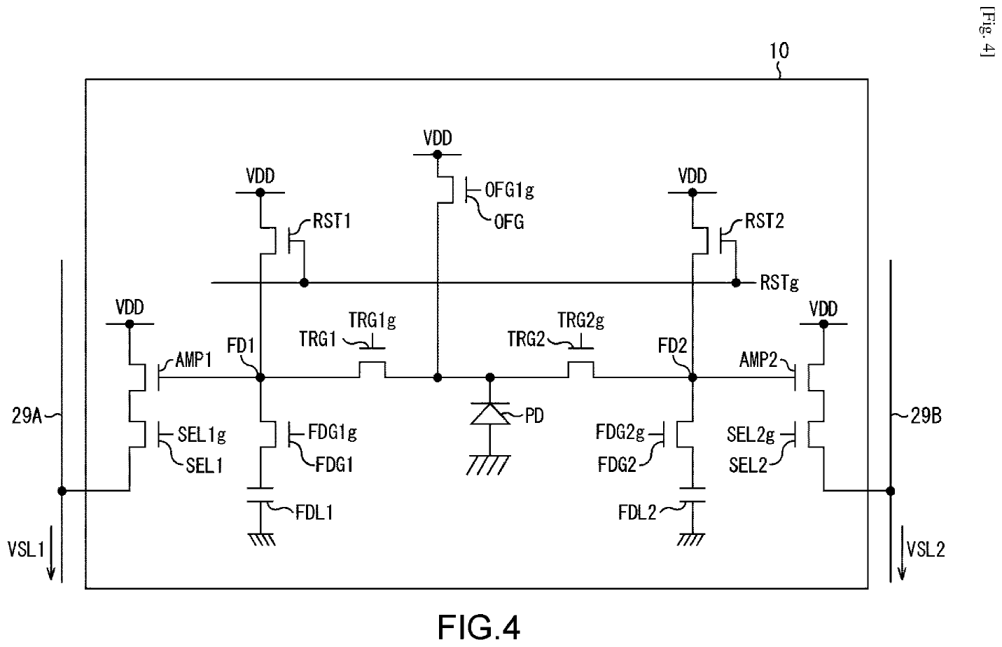

FIG. 4 shows the circuit configuration of the pixel 10 two-dimensionally arranged in the pixel array unit 21.

The pixel 10 includes a photodiode PD as a photoelectric conversion element. Further, the pixel 10 has two transfer transistors TRG, two floating diffusion regions FD, two additional capacitors FDL, switching transistors FDG, two amplification transistors AMP, two reset transistors RST, and two selection transistors SEL. In addition, the pixel 10 has a charge discharging transistor OFG.

Here, in order to be distinguished from each other, the two transfer transistors TRG, the two floating diffusion regions FD, the two additional capacitors FDL, the two switching transistors FDG, the two amplification transistors AMP, the two reset transistors RST, and the two selection transistors SEL in the pixel 10 will be called transfer transistors TRG1 and TRG2, floating diffusion regions FDG1 and FDG2, additional capacitors FDL1 and FDL2, switching transistors FDG1 and FDG2, amplification transistors AMP1 and AMP2, reset transistors RST1 and RST2, and selection transistors SEL1 and SEL2, respectively, as shown in FIG. 4.

The transfer transistors TRG, the switching transistors FDG, the amplification transistors AMP, the selection transistors SEL, the reset transistors RST, and the charge discharging transistor OFG include, for example, N-type MOS transistors.

When a transfer drive signal TRG1g that is supplied to the gate electrode of the transfer transistor TRG1 is brought into an active state, the transfer transistor TRG1 is brought into a conductive state correspondingly and transfers charges accumulated in the photodiode PD to the floating diffusion region FD1. When a transfer drive signal TRG2g that is supplied to the gate electrode of the transfer transistor TRG2 is brought into an active state, the transfer transistor TRG2 is brought into a conductive state correspondingly and transfers charges accumulated in the photodiode PD to the floating diffusion region FD2.

The floating diffusion regions FD1 and FD2 are charge accumulation units that temporarily retain charges transferred from the photodiode PD.

When a FD drive signal FDG1g that is supplied to the gate electrode of the switching transistor FDG1 is brought into an active state, the switching transistor FDG1 is brought into a conductive state correspondingly and connects the additional capacitor FDL1 to the floating diffusion region FD1. When a FD drive signal FDG2g that is supplied to the gate electrode of the switching transistor FDG2 is brought into an active state, the switching transistor FDG2 is brought into a conductive state correspondingly and connects the additional capacitor FDL2 to the floating diffusion region FD2. The additional capacitors FDL1 and FDL2 are formed by the interconnection capacity 64 of FIG. 2.

When a reset drive signal RSTg that is supplied to the gate electrode of the reset transistor RST1 is brought into an active state, the reset transistor RST1 is brought into a conductive state correspondingly and resets the potential of the floating diffusion region FD1. When the reset drive signal RSTg that is supplied to the gate electrode of the reset transistor RST2 is brought into an active state, the reset transistor RST2 is brought into a conductive state correspondingly and resets the potential of the floating diffusion region FD2. Note that when the reset transistors RST1 and RST2 are brought into an active state, the switching transistors FDG1 and FDG2 are also simultaneously brought into an active state and the additional capacitors FDL1 and FDL2 are also reset.

For example, in a high-illumination state in which the amount of incident light is great, the vertical drive unit 22 brings the switching transistors FDG1 and FDG2 into an active state to connect the floating diffusion region FD1 and the additional capacitor FDL1 to each other and connect the floating diffusion region FD2 and the additional capacitor FDL2 to each other. Thus, it is possible to accumulate more charges in a high-illumination state.

On the other hand, in a low-illumination state in which the amount of incident light is small, the vertical drive unit 22 brings the switching transistors FDG1 and FDG2 into an inactive state to separate the additional capacitors FDL1 and FDL2 from the floating diffusion regions FD1 and FD2, respectively. Thus, it is possible to increase conversion efficiency.

When a discharge drive signal OFG1g that is supplied to the gate electrode of the charge discharging transistor OFG is brought into an active state, the charge discharging transistor OFG is brought into a conductive state correspondingly and discharges charges accumulated in the photodiode PD.

When the source electrode of the amplification transistor AMP1 is connected to a vertical signal line 29A via the selection transistor SEL1, the amplification transistor AMP1 connects to a constant current source (not shown) to constitute a source follower circuit. When the source electrode of the amplification transistor AMP2 is connected to a vertical signal line 29B via the selection transistor SEL1, the amplification transistor AMP2 connects to a constant current source (not shown) to constitute a source follower circuit.

The selection transistor SEL1 is connected between the source electrode of the amplification transistor AMP1 and the vertical signal line 29A. When a selection signal SELlg that is supplied to the gate electrode of the selection transistor SEL1 is brought into an active state, the selection transistor SEL1 is brought into a conductive state correspondingly and outputs a detection signal VSL1 output from the amplification transistor AMP1 to the vertical signal line 29A.

The selection transistor SEL2 is connected between the source electrode of the amplification transistor AMP2 and the vertical signal line 29B. When a selection signal SEL2g that is supplied to the gate electrode of the selection transistor SEL2 is brought into an active state, the selection transistor SEL2 is brought into a conductive state correspondingly and outputs a detection signal VSL2 output from the amplification transistor AMP2 to the vertical signal line 29B.

The transfer transistors TRG1 and TRG2, the switching transistors FDG1 and FDG2, the amplification transistors AMP1 and AMP2, the selection transistors SEL1 and SEL2, and the charge discharging transistor OFG of the pixel 10 are controlled by the vertical drive unit 22.

In the pixel circuit of FIG. 4, the additional capacitors FDL1 and FDL2 and the switching transistors FDG1 and FDG2 that control the connection of the additional capacitors FDL1 and FDL2 may be omitted. However, when the additional capacitors FDL are provided and appropriately used according to an incident light amount, it is possible to secure a high dynamic range.

The operation of the pixels 10 will be briefly described.

First, before starting light reception, all the pixels perform a reset operation to reset the charges of the pixels 10. That is, the charge discharging transistor OFG, the reset transistors RTS1 and RST2, and the switching transistors FDG1 and FDG2 are turned on, and the accumulated charges of the photodiode PD, the floating diffusion regions FD1 and FD2, and the additional capacitors FDL1 and FDL2 are discharged.

After discharging the accumulated charges, all the pixels start the light reception.

In a light reception period, the transfer transistors TRG1 and TRG2 are alternately driven. That is, in a first period, the transfer transistor TRG1 is controlled to be turned on, and the transfer transistor TRG2 is controlled to be turned off. In the first period, charges generated by the photodiode PD are transferred to the floating diffusion region FD1. In a second period next to the first period, the transfer transistor TRG1 is controlled to be turned off, and the transfer transistor TRG2 is controlled to be turned on. In the second period, charges generated by the photodiode PD are transferred to the floating diffusion region FD2. Thus, the charges generated by the photodiode PD are distributed to and accumulated in the floating diffusion regions FD1 and FD2.

Then, after the end of the light reception period, the respective pixels 10 of the pixel array unit 21 are line-sequentially selected. In the selected pixels 10, the selection transistors SEL1 and SEL2 are turned on. Thus, the charges accumulated in the floating diffusion region FD1 are output as the detection signal VSL1 to the column processing unit 23 via the vertical signal line 29A. The charges accumulated in the floating diffusion region FD2 are output as the detection signal VSL2 to the column processing unit 23 via the vertical signal line 29B.

One light reception operation ends in the manner described above, and a next light reception operation starting from a reset operation is performed.

Reflected light received by the pixels 10 is delayed according to a distance to a target object on the basis of a timing at which the reflected light is irradiated from the light source. The distribution ratio of the charges accumulated in the two floating diffusion regions FD1 and FD2 changes depending on a delayed time corresponding to the distance to the target object. Therefore, it is possible to calculate the distance to the object on the basis of the distribution ratio of the charges accumulated in the two floating diffusion regions FD1 and FD2.

<4. Plan View of Pixel>

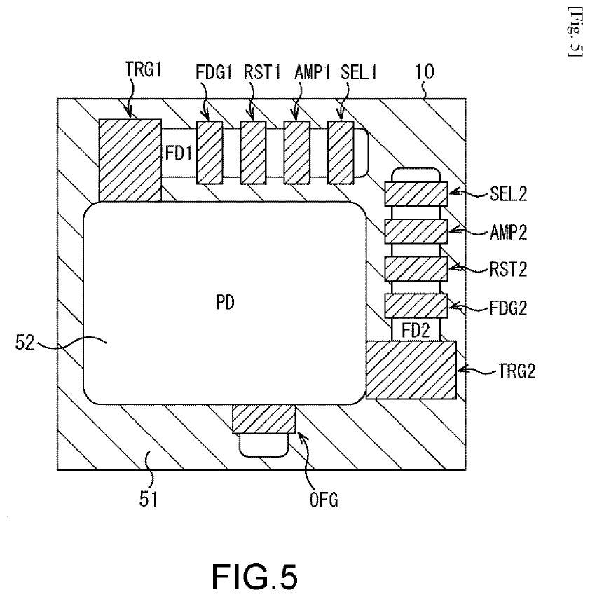

FIG. 5 is a plan view showing an arrangement example of the pixel circuit shown in FIG. 4.

In FIG. 5, a horizontal direction corresponds to the row direction (horizontal direction) in FIG. 1, and a vertical direction corresponds to the column direction (vertical direction) in FIG. 1.

As shown in FIG. 5, the photodiode PD is formed as the N-type semiconductor region 52 in the region of the central part of the rectangular pixel 10.

On the outside of the photodiode PD and along one prescribed side of the four sides of the rectangular pixel 10, the transfer transistor TRG1, the switching transistor FDG1, the reset transistor RST1, the amplification transistor AMP1, and the selection transistor SEL1 are linearly arranged side by side. Further, on the outside of the photodiode PD and along another side of the four sides of the rectangular pixel 10, the transfer transistor TRG2, the switching transistor FDG2, the reset transistor RST2, the amplification transistor AMP2, and the selection transistor SEL2 are linearly arranged side by side.

On another side different from the two sides on which the transfer transistors TRG, the switching transistors FDG, the reset transistors RST, the amplification transistors AMP, and the selection transistors SEL are formed, the charge discharging transistor OFG is arranged.

Note that the arrangement of the pixel circuit is not limited to the example shown in FIG. 4 but may include other arrangements.

<5. Another Circuit Configuration Example of Pixel>

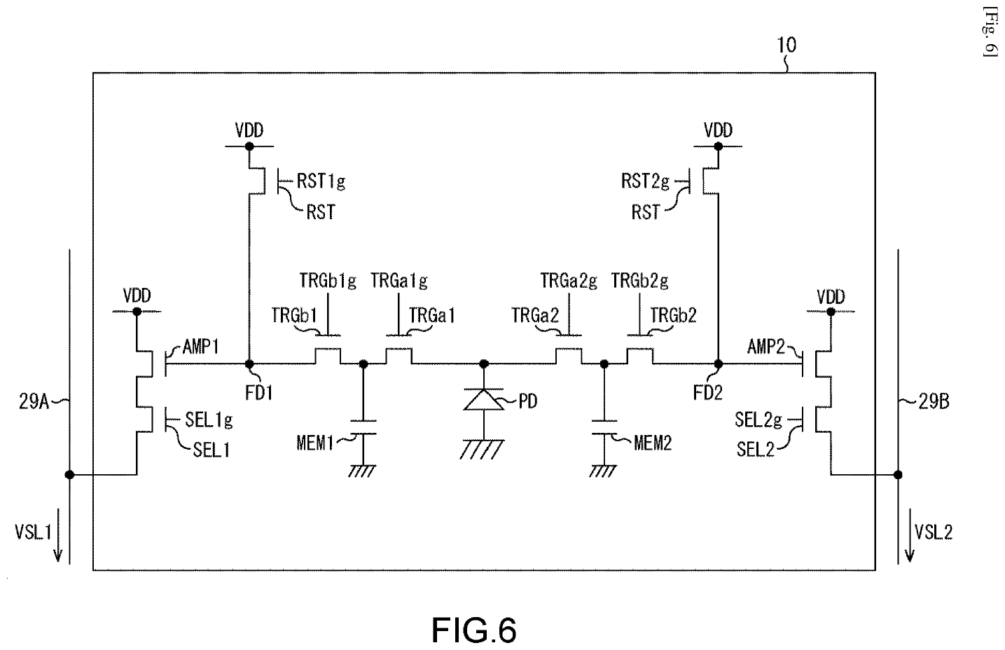

FIG. 6 shows another circuit configuration example of the pixel 10.

In FIG. 6, portions corresponding to those shown in FIG. 4 will be denoted by the same reference symbols, and their descriptions will be appropriately omitted.

The pixel 10 includes a photodiode PD as a photoelectric conversion element.

Further, the pixel 10 has two first transfer transistors TRGa, two second transfer transistors TRGb, two memories MEM, two floating diffusion regions FD, two reset transistors RST, two amplification transistors AMP, and two selection transistors SEL.

Here, in order to be distinguished from each other, the two first transfer transistors TRGa, the two second transfer transistors TRGb, the two memories MEM, the two floating diffusion regions FD, the two reset transistors RST, the two amplification transistors AMP, and the two selection transistors SEL in the pixel 10 will be called first transfer transistors TRGa1 and TRGa2, second transfer transistors TRGb1 and TRGb2, transfer transistors TRG1 and TRG2, memories MEM1 and MEM2, floating diffusion regions FD1 and FD2, amplification transistors AMP1 and AMP2, and selection transistors SEL1 and SEL2, respectively, as shown in FIG. 6.

Accordingly, the comparison between the pixel circuit of FIG. 4 and the pixel circuit of FIG. 6 shows that the transfer transistors TRG are changed to the two types of the first transfer transistors TRGa and the second transfer transistors TRGb, and that the memories MEM are added. Further, the additional capacitors FDL and the switching transistors FDG are omitted.

The first transfer transistors TRGa, the second transfer transistors TRGb, the reset transistors RST, the amplification transistors AMP, and the selection transistors SEL include, for example, N-type MOS transistors.

In the pixel circuit shown in FIG. 4, charges generated by the photodiode PD are transferred to and retained by the floating diffusion regions FD1 and FD2. However, in the pixel circuit of FIG. 6, charges are transferred to and retained by the memories MEM1 and MEM2 provided as charge accumulation units.

That is, when a first transfer drive signal TRGa1g that is supplied to the gate electrode of the first transfer transistor TRGa1 is brought into an active state, the first transfer transistor TRGa1 is brought into a conductive state correspondingly and transfers charges accumulated in the photodiode PF to the memory MEM1. When a first transfer drive signal TRGa2g that is supplied to the gate electrode of the first transfer transistor TRGa2 is brought into an active state, the first transfer transistor TRGa2 is brought into a conductive state correspondingly and transfers the charges accumulated in the photodiode PF to the memory MEM2.

Further, when a second transfer drive signal TRGb1g that is supplied to the gate electrode of the second transfer transistor TRGb1 is brought into an active state, the second transfer transistor TRGb1 is brought into a conductive state correspondingly and transfers the charges accumulated in the memory MEM1 to the floating diffusion region FD1. When a second transfer drive signal TRGb2g that is supplied to the gate electrode of the second transfer transistor TRGb2 is brought into an active state, the second transfer transistor TRGb2 is brought into a conductive state correspondingly and transfers the charges accumulated in the memory MEM2 to the floating diffusion region FD2.

When a reset drive signal RST1g that is supplied to the gate electrode of the reset transistor RST1 is brought into an active state, the reset transistor RST1 is brought into a conductive state correspondingly and resets the potential of the floating diffusion region FD1. When a reset drive signal RST2g that is supplied to the gate electrode of the reset transistor RST2 is brought into an active state, the reset transistor RST2 is brought into a conductive state correspondingly and resets the potential of the floating diffusion region FD2. Note that when the reset transistors RST1 and RST2 are brought into an active state, the second transfer transistors TRGb1 and TRGb2 are also simultaneously brought into an active state and the memories MEM1 and MEM2 are also reset.

In the pixel circuit of FIG. 6, the charges generated by the photodiode PD are distributed to and accumulated in the memories MEM1 and MEM2. Then, the charges retained by the memories MEM1 and MEM2 are transferred to the floating diffusion regions FD1 and FD2, respectively, and output from the pixel 10 at a timing at which the charges are read.

<6. Plan View of Pixel>

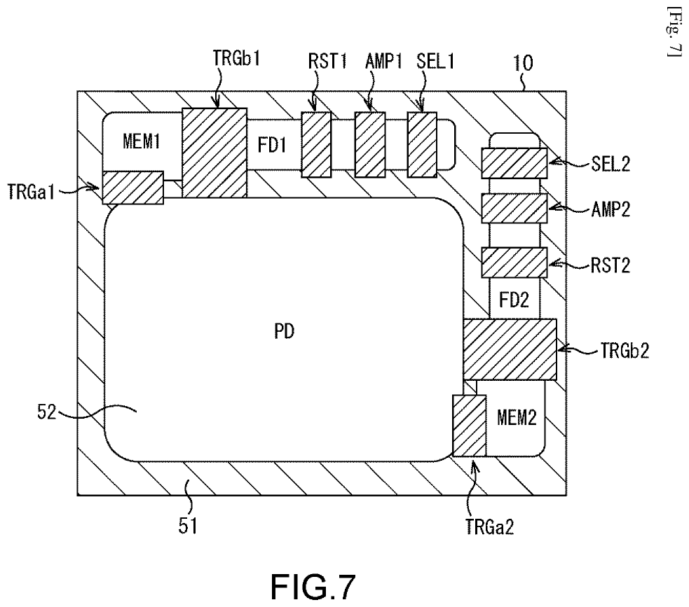

FIG. 7 is a plan view showing an arrangement example of the pixel circuit shown in FIG. 6.

In FIG. 7, a horizontal direction corresponds to the row direction (horizontal direction) in FIG. 1, and a vertical direction corresponds to the column direction (vertical direction) in FIG. 1.

As shown in FIG. 7, the photodiode PD is formed as the N-type semiconductor region 52 in the region of the central part of the rectangular pixel 10.

On the outside of the photodiode PD and along one prescribed side of the four sides of the rectangular pixel 10, the first transfer transistor TRGa1, the second transfer transistor TRGb1, the reset transistor RST1, the amplification transistor AMP1, and the selection transistor SEL1 are linearly arranged side by side. Further, on the outside of the photodiode PD and along another side of the four sides of the rectangular pixel 10, the first transfer transistor TRGa2, the second transfer transistor TRGb2, the reset transistor RST2, the amplification transistor AMP2, and the selection transistor SEL2 are linearly arranged side by side. The memories MEM1 and MEM2 are formed by, for example, embedding-type N-type diffusion regions.

Note that the arrangement of the pixel circuit is not limited to the example shown in FIG. 7 but may include other arrangements.

<7. Cross-Sectional View Related to Second Configuration Example of Pixel>

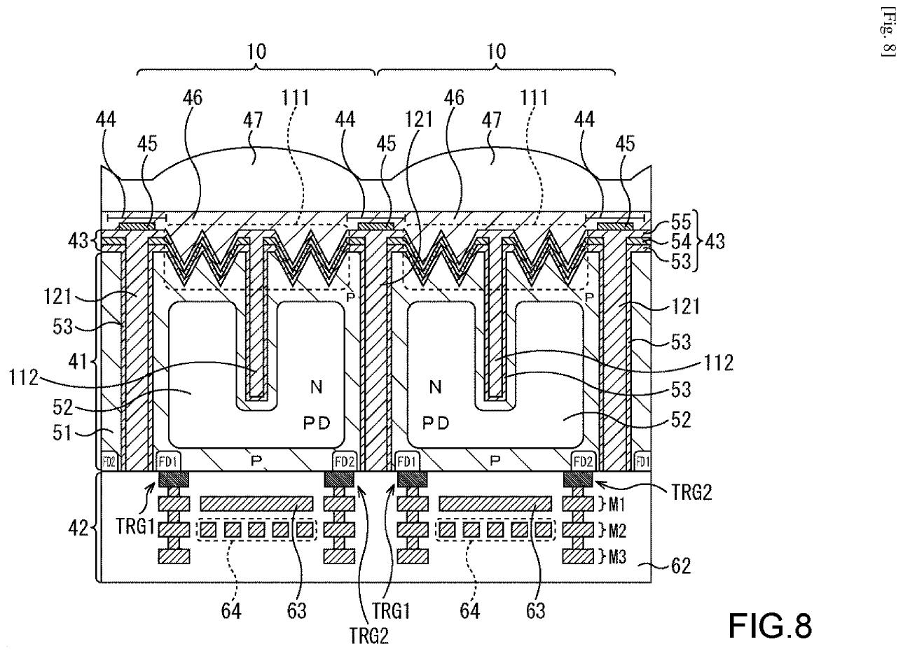

FIG. 8 is a cross-sectional view showing a second configuration example of the pixel 10.

In FIG. 8, portions corresponding to those of the first configuration example shown in FIG. 2 will be denoted by the same reference symbols, and their descriptions will be appropriately omitted.

The second configuration example of FIG. 8 is different in that the interpixel trench portion 61 formed to be engraved up to a prescribed depth, at which the interpixel trench portion 61 does not penetrate the semiconductor substrate 41, from the rear surface side (the side of the on-chip lens 47) of the semiconductor substrate 41 in the first configuration example of FIG. 2 is replaced by an interpixel trench portion 121 that penetrates the semiconductor substrate 41. The second configuration example is similar to the first configuration example in other points.

The interpixel trench portion 121 is formed in such a manner that a trench is formed so as to penetrate a substrate surface on a side opposite to the rear surface side (the side of the on-chip lens 47) or the front surface side of the semiconductor substrate 41, and that the silicon oxide film 55 that is the material of the uppermost layer of the antireflection film 43 is then embedded in the trench. Besides an insulating film such as the silicon oxide film 55, the material embedded in the trench as the interpixel trench portion 121 may be, for example, a metal material such as tungsten (W), aluminum (Al), titanium (Ti), and titanium nitride (TiN) or polysilicon. Further, like the first configuration example, the interpixel trench portion 121 and the in-pixel trench portion 112 may not be made of the same material but may be made of different materials.

With the formation of such an interpixel trench portion 121, it is possible to electrically completely separate adjacent pixels from each other. Thus, the interpixel trench portion 121 prevents incident light from penetrating an adjacent pixel 10 while confining the same inside the own pixel and prevents the leakage of incident light from the adjacent pixel 10.

Further, with the formation of the in-pixel trench portion 112 at the central part of a pixel, it is possible to increase the probability of confining incident light inside the own pixel. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

In the manner described above, it is possible to further increase the amount of infrared light photoelectrically converted inside the semiconductor substrate 41 and improve quantum efficiency (QE), that is, sensitivity to the infrared light in the second configuration example as well.

<8. Cross-Sectional View Related to Third Configuration Example of Pixel>

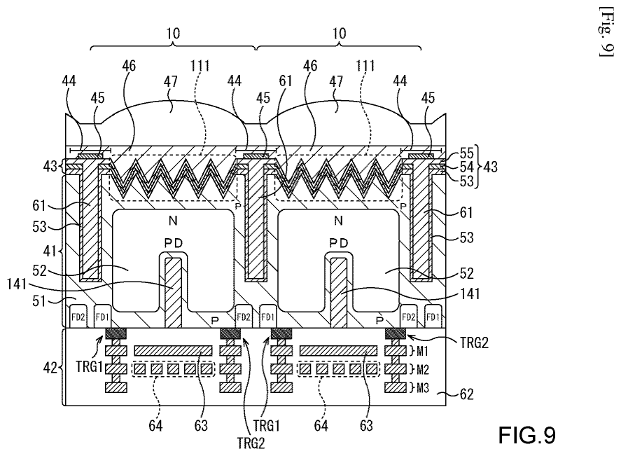

FIG. 9 is a cross-sectional view showing a third configuration example of the pixel 10.

In FIG. 9, portions corresponding to those of the first configuration example shown in FIG. 2 will be denoted by the same reference symbols, and their descriptions will be appropriately omitted.

The third configuration example of FIG. 9 is different in that the in-pixel trench portion 112 formed to be engraved up to a prescribed depth, at which the interpixel trench portion 61 does not penetrate the semiconductor substrate 41, from the rear surface side (the side of the on-chip lens 47) of the semiconductor substrate 41 in the first configuration example of FIG. 2 is replaced by an in-pixel trench portion 141 formed to be engraved up to a prescribed depth from the front surface side of the semiconductor substrate 41. The third configuration example is common to the first configuration example in other points.

The in-pixel trench portion 141 is formed in such a manner that a trench is formed up to a prescribed depth from the front surface side (the side of the multilayer interconnection layer 42) of the semiconductor substrate 41, and that a silicon oxide film is then embedded in the trench. Besides an insulating film such as a silicon oxide film, the material embedded in the trench as the in-pixel trench portion 141 may be, for example, a metal material such as tungsten (W), aluminum (Al), titanium (Ti), and titanium nitride (TiN) or polysilicon. Further, like the first configuration example, the interpixel trench portion 61 and the in-pixel trench portion 141 may not be made of the same material but may be made of different materials.

As shown in FIGS. 3A and 3B, the in-pixel trench portion 141 is formed into a cross shape so that the rectangular planar region of the pixel 10 is halved in each of the row direction and the column direction to be divided into four regions in a plan view.

With the formation of such an in-pixel trench portion 141, it is possible to increase the probability of confining incident light inside an own pixel. Further, the interpixel trench portion 61 is also formed at the pixel boundary portion 44 to prevent incident light from penetrating an adjacent pixel 10 while confining the same inside the own pixel and prevent the leakage of incident light from the adjacent pixel 10.

Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

In the manner described above, it is possible to further increase the amount of infrared light photoelectrically converted inside the semiconductor substrate 41 and improve quantum efficiency (QE), that is, sensitivity to the infrared light in the third configuration example as well.

Note that the in-pixel trench portion 112 or the in-pixel trench portion 141 in the first configuration example to the third configuration example described above is formed into a cross planar shape in which the rectangular planar region of the pixel 10 is divided into two regions in each of the row direction and the column direction in a plan view. However, the in-pixel trench portion 112 or the in-pixel trench portion 141 may be formed into a planar shape in which the rectangular planar region of the pixel 10 is divided into three regions in each of the row direction and the column direction.

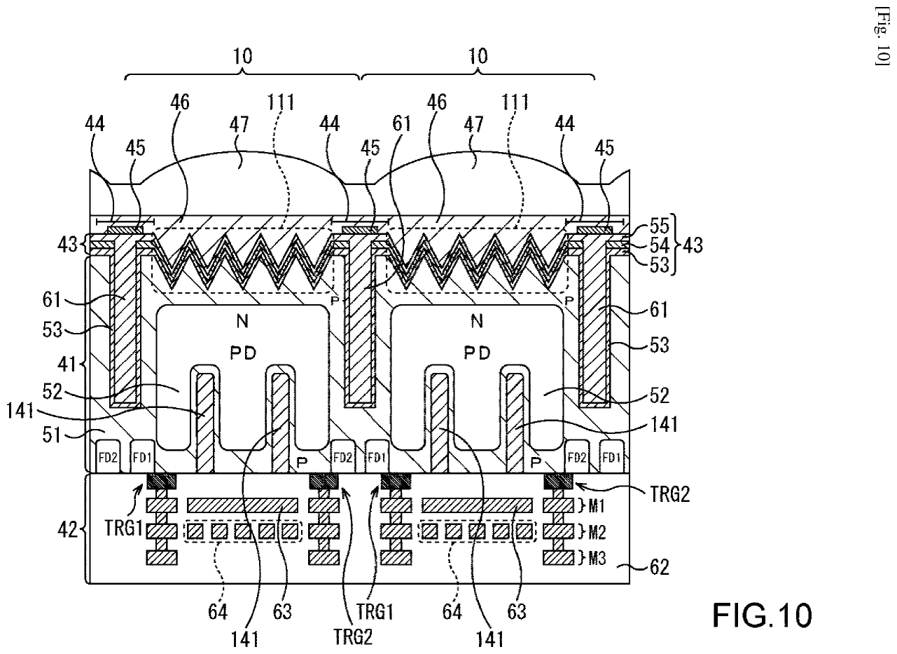

FIG. 10 is a cross-sectional view showing a modified example of the pixel 10 according to the third configuration example.

The modified example of FIG. 10 is different from the third configuration example of FIG. 9 in the shape and the arrangement of the in-pixel trench portion 141. The modified example is common to the third configuration example of FIG. 9 in other points.

In the modified example of FIG. 10, the in-pixel trench portion 141 is formed to be engraved up to a prescribed depth from the front surface side (the side of the multilayer interconnection layer 42) of the semiconductor substrate 41 at a planar position at which the rectangular planar region of the pixel 10 is divided into three regions in each of the row direction and the column direction in a plan view.

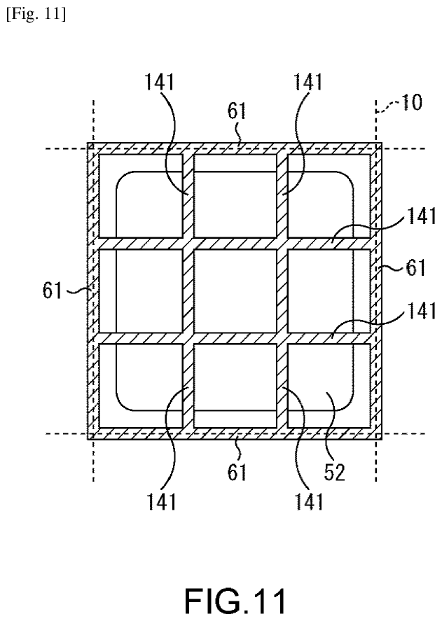

FIG. 11 is a plan view of the interpixel trench portion 61 and the in-pixel trench portion 141 when seen from the front surface side of the semiconductor substrate 41.

The in-pixel trench portion 141 is formed at a planar position at which the rectangular planar region of the pixel 10 is divided into three regions in each of the row direction and the column direction in a plan view. However, as is clear from the cross-sectional view of FIG. 10, the in-pixel trench portion 141 is formed up to only a depth at which the in-pixel trench portion 141 does not penetrate the photodiode PD. Therefore, the region of the photodiode PD remains intact.

Note that when the rectangular planar region of the pixel 10 is divided into three regions in each of the row direction and the column direction, the interpixel trench portion 61 and the in-pixel trench portion 141 may not be formed at their intersections at which the trench portions cross each other as shown in FIG. 3B.

When the in-pixel trench portion 141 is formed from the front surface side (the side of the multilayer interconnection layer 42) of the semiconductor substrate 41, there is a possibility that the in-pixel trench portion 141 cannot be formed as in FIG. 3 or FIG. 11 since pixel transistors such as the transfer transistors TRG, the reset transistors RST, the amplification transistors AMP, and the selection transistors SEL are formed on the front surface side of the semiconductor substrate 41 as shown in FIGS. 5 and 7.

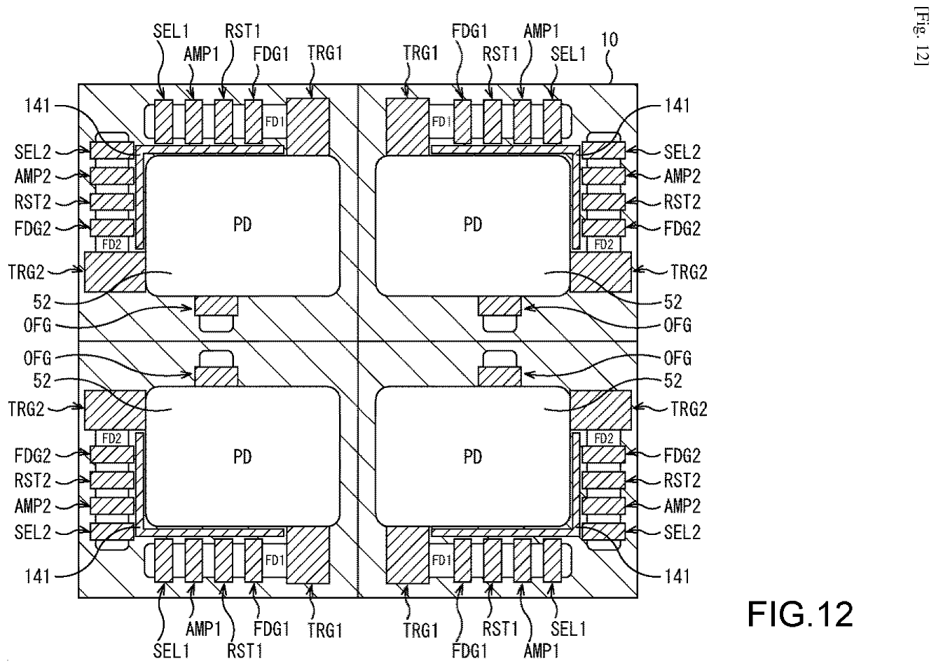

FIG. 12 is a plan view showing an arrangement example of the in-pixel trench portion 141 according to the arrangement of the pixel transistors.

When priority is assigned to the arrangement of the pixel transistors, the in-pixel trench portion 141 can be formed between the transfer transistors TRG, the switching transistors FDG, the reset transistors RST, the amplification transistors AMP, and the selection transistors SEL linearly arranged side by side and the N-type semiconductor region 52 constituting the photodiode PD as shown in FIG. 12.

When the in-pixel trench portion 141 is formed between the N-type semiconductor region 52 constituting the photodiode PD and the plurality of pixel transistors linearly arranged side by side as described above, the arrangement of the in-pixel trench portion 141 has anisotropy on a pixel-by-pixel basis. Therefore, four (2×2) pixels can be symmetrically arranged as shown in FIG. 12.

<9. Cross-Sectional View Related to Fourth Configuration Example of Pixel>

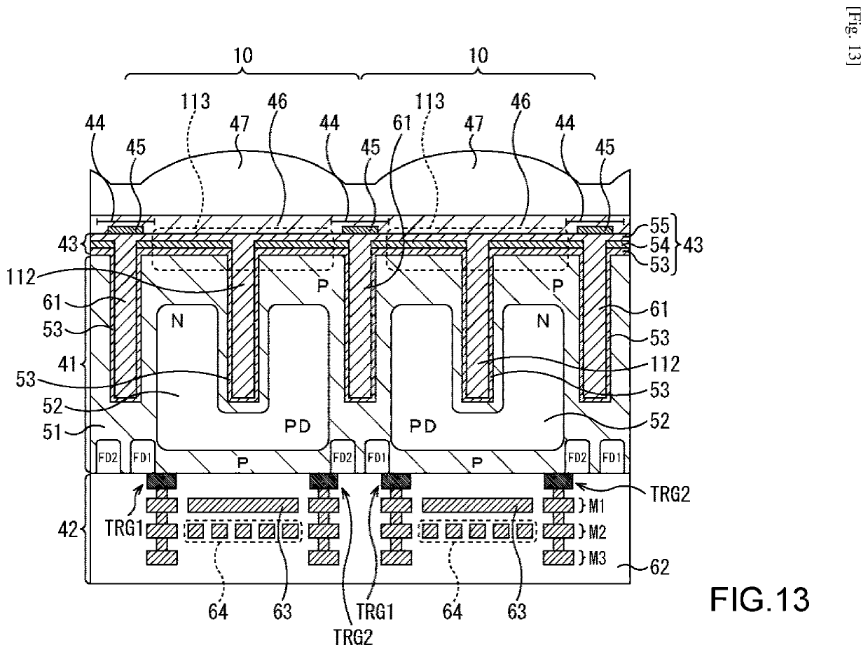

FIG. 13 is a cross-sectional view showing a fourth configuration example of the pixel 10.

In FIG. 13, portions corresponding to those of the first configuration example shown in FIG. 2 will be denoted by the same reference symbols, and their descriptions will be appropriately omitted.

The fourth configuration example of the pixel 10 shown in FIG. 13 is common to the first configuration example shown in FIG. 2 in that the interpixel trench portion 61 is formed at the pixel boundary portion 44, and that the in-pixel trench portion 112 is formed at the central part of the pixel.

On the other hand, the fourth configuration example shown in FIG. 13 is different from the first configuration example shown in FIG. 2 in that the moth-eye structure portion 111 that is an irregularity structure having periodicity is not formed but a flat portion 113 is formed on the light incident surface on the rear surface side of the semiconductor substrate 41. In the flat portion 113, the antireflection film 43 in which the hafnium oxide film 53, the aluminum oxide film 54, and the silicon oxide film 55 are laminated with each other is formed to be flat.

Like this fourth configuration example, the pixel 10 may have a configuration in which the moth-eye structure portion 111 on the rear surface side of the semiconductor substrate 41 is omitted and replaced by the flat portion 113.

In the fourth configuration example as well in which the moth-eye structure portion 111 on the rear surface of the substrate is replaced by the flat portion 113, the pixel 10 has the interpixel trench portion 61 and the in-pixel trench portion 112 to prevent incident light from penetrating an adjacent pixel 10 while confining the same inside the own pixel and prevent the leakage of incident light from the adjacent pixel 10. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

In the manner described above, it is possible to further increase the amount of infrared light photoelectrically converted inside the semiconductor substrate 41 and improve quantum efficiency (QE), that is, sensitivity to the infrared light in the fourth configuration example as well.

Note that although the fourth configuration example of FIG. 13 has a configuration in which the moth-eye structure portion 111 of the first configuration example shown in FIG. 2 is omitted and replaced by the flat portion 113, each of the second configuration example and the third configuration example described above may also similarly have a configuration in which the moth-eye structure portion 111 on the rear surface of the substrate is replaced by the flat portion 113.

<10. Cross-Sectional View Related to Fifth Configuration Example of Pixel>

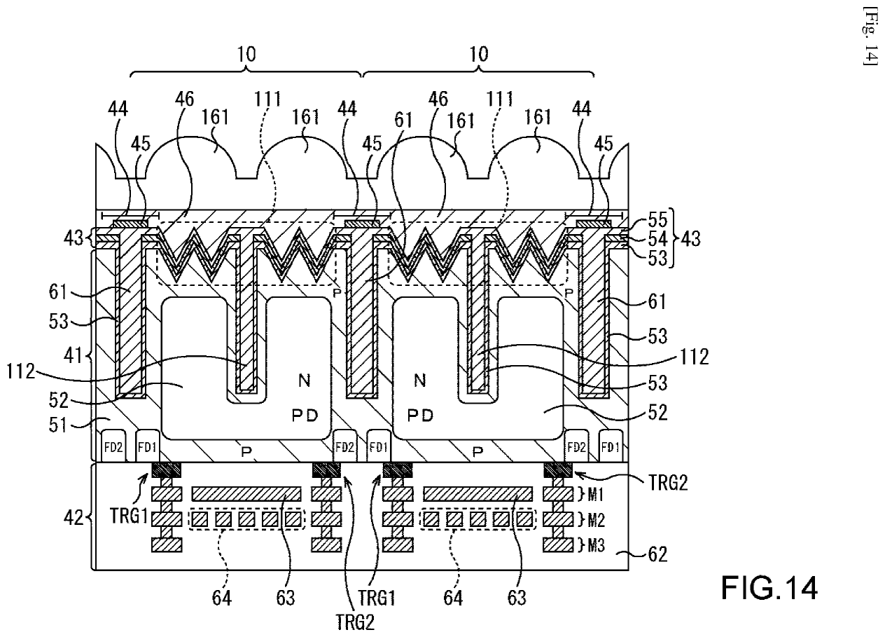

FIG. 14 is a cross-sectional view showing a fifth configuration example of the pixel 10.

In FIG. 14, portions corresponding to those of the first configuration example shown in FIG. 2 will be denoted by the same reference symbols, and their descriptions will be appropriately omitted.

The fifth configuration example of the pixel 10 shown in FIG. 14 is different from the first configuration example shown in FIG. 2 in that the on-chip lens 47 of the first configuration example is replaced by on-chip lenses 161 formed on the upper surface on the light incident surface side of the semiconductor substrate 41. The fifth configuration example is common to the first configuration example in other points.

More specifically, in the first configuration example shown in FIG. 2, the one on-chip lens 47 is formed on the upper surface of the semiconductor substrate 41 on the light incident surface side of the one photodiode PD.

On the other hand, four on-chip lenses 161 are formed on the upper surface of the semiconductor substrate 41 on the light incident surface side of the one photodiode PD in the fifth configuration example of FIG. 14.

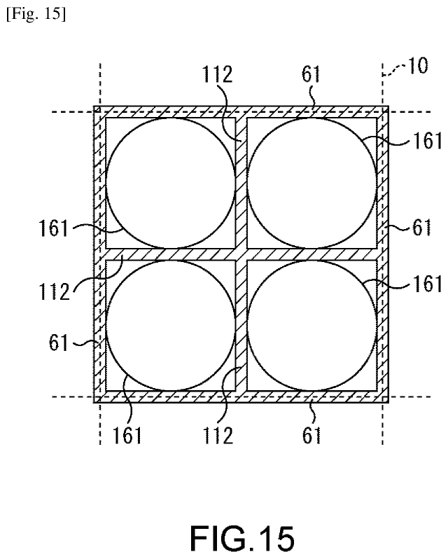

FIG. 15 is a plan view showing the arrangement of the on-chip lenses 161 of the pixel 10 according to the fifth configuration example.

In the fifth configuration example, the in-pixel trench portion 112 arranged in a cross shape separates the N-type semiconductor region 52 serving as the photodiode PD into four regions at a prescribed depth, and the on-chip lenses 161 are arranged corresponding to the respective separated regions. As a result, the four (2×2) on-chip lenses 161 are arranged with respect to one pixel.

As described above, the pixel 10 can have a configuration in which a plurality of on-chip lenses 161 is arranged with respect to one photodiode PD. For example, when the N-type semiconductor region 52 serving as the photodiode PD is separated into nine regions at a prescribed depth like the modified example of the third configuration example shown in FIG. 10, nine (3×3) on-chip lenses 161 can be formed on the upper surface of the semiconductor substrate 41.

In the fifth configuration example as well in which the plurality of on-chip lenses 161 is formed in one pixel, the pixel 10 has the interpixel trench portion 61 and the in-pixel trench portion 112 to prevent incident light from penetrating an adjacent pixel 10 while confining the same inside the own pixel and prevent the leakage of incident light from the adjacent pixel 10. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

In the manner described above, it is possible to further increase the amount of infrared light photoelectrically converted inside the semiconductor substrate 41 and improve quantum efficiency (QE), that is, sensitivity to the infrared light in the fifth configuration example as well.

Note that although the fifth configuration example of FIG. 14 has a configuration in which the on-chip lens 47 of the first configuration example shown in FIG. 2 is replaced by the plurality of on-chip lenses 161, each of the second configuration example to the fourth configuration example described above may also similarly have a configuration in which the on-chip lens 47 is replaced by the plurality of on-chip lenses 161.

<11. Cross-Sectional View Related to Sixth Configuration Example of Pixel>

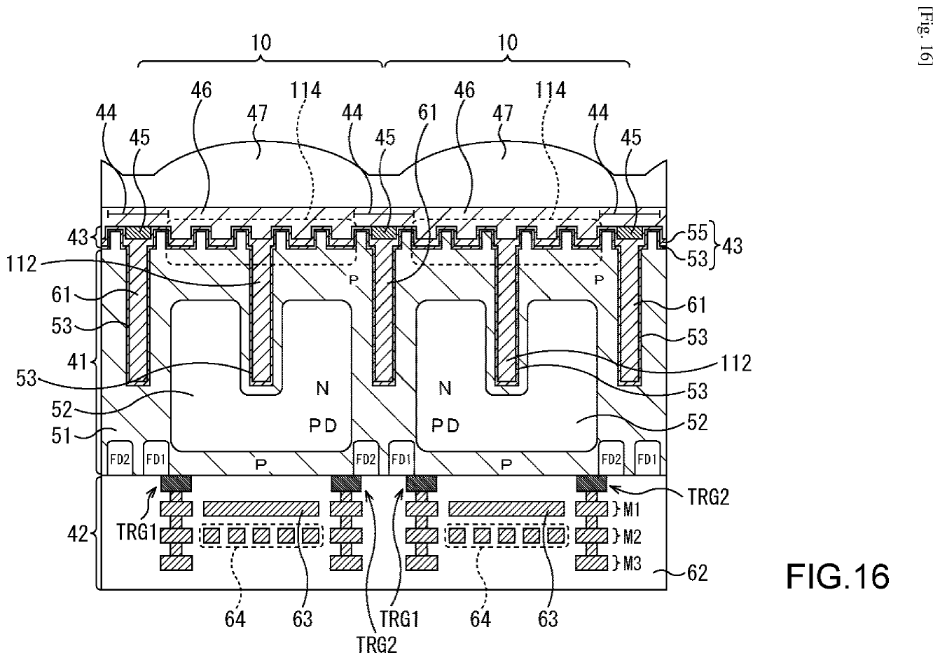

FIG. 16 is a cross-sectional view showing a sixth configuration example of the pixel 10.

In FIG. 16, portions corresponding to those of the first configuration example shown in FIG. 2 will be denoted by the same reference symbols, and their descriptions will be appropriately omitted.

In the sixth configuration example of the pixel 10 shown in FIG. 16, a moth-eye structure portion 114 having an irregularity structure different from that of the moth-eye structure portion 111 of the first configuration example shown in FIG. 2 is formed over the forming region of the photodiode PD.

Specifically, in the first configuration example shown in FIG. 2, the shape of the moth-eye structure portion 111 has the pyramid structure in which the quadrangular pyramid shapes are regularly arranged side by side.

On the other hand, in the sixth configuration example of FIG. 16, the shape of the moth-eye structure portion 114 has an irregularity structure in which recessed portions having a surface parallel to the semiconductor substrate 41 and engraved by a prescribed amount in a substrate depth direction are arranged side by side at a constant cycle. Note that the antireflection film 43 includes the two layers of the hafnium oxide film 53 and the silicon oxide film 55 in FIG. 16. However, the antireflection film 43 may include three layers like other configuration examples, or may include a single layer.

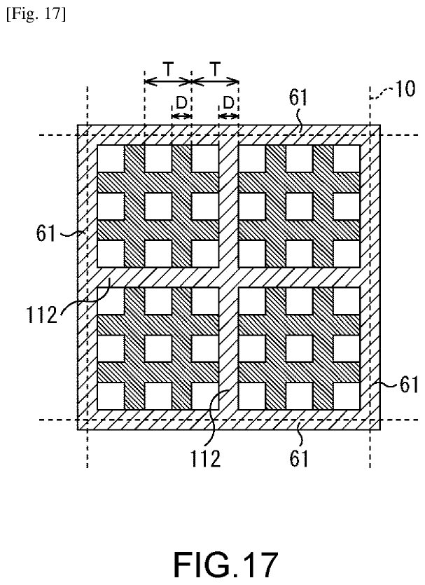

FIG. 17 is a plan view showing the arrangement of the recessed portions of the moth-eye structure portion 114 and the interpixel trench portion 61 and the in-pixel trench portion 112 in the sixth configuration example.

In FIG. 17, the interpixel trench portion 61 is formed at the boundary portion of the pixel 10, and the in-pixel trench portion 112 is formed into a cross shape so that the rectangular planar region of the pixel 10 is halved in each of the row direction and the column direction to be divided into four regions.

The regions of the recessed portions having a width D of the irregularity structure arranged at a cycle T of the moth-eye structure portion 114 are shown by a pattern having a pitch smaller than those of the interpixel trench portion 61 and the in-pixel trench portion 112.

As shown in FIG. 17, the in-pixel trench portion 112 is arranged without disturbing the periodicity of the irregularity structure of the moth-eye structure portion 114. In other words, the in-pixel trench portion 112 is formed in a part of the recessed portions of the moth-eye structure portion 114 that is an irregularity structure having periodicity.

In the sixth configuration example as well in which the in-pixel trench portion 112 is arranged in a part of the recessed portions where the irregularity structure is periodically arranged, the pixel 10 has the interpixel trench portion 61 and the in-pixel trench portion 112 to prevent incident light from penetrating an adjacent pixel 10 while confining the same inside the own pixel and prevent the leakage of incident light from the adjacent pixel 10. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

In the manner described above, it is possible to further increase the amount of infrared light photoelectrically converted inside the semiconductor substrate 41 and improve quantum efficiency (QE), that is, sensitivity to the infrared light in the sixth configuration example as well.

Note that although the sixth configuration example of FIG. 16 has a configuration in which the moth-eye structure portion 114 having a shape different from that of the moth-eye structure portion 111 of the first configuration example is formed on the light incident surface that is the rear surface side of the semiconductor substrate 41, each of the second configuration example to the fifth configuration example described above may also similarly have a configuration in which the moth-eye structure portion 114 is arranged.

<12. Cross-Sectional View Related to Seventh Configuration Example of Pixel>

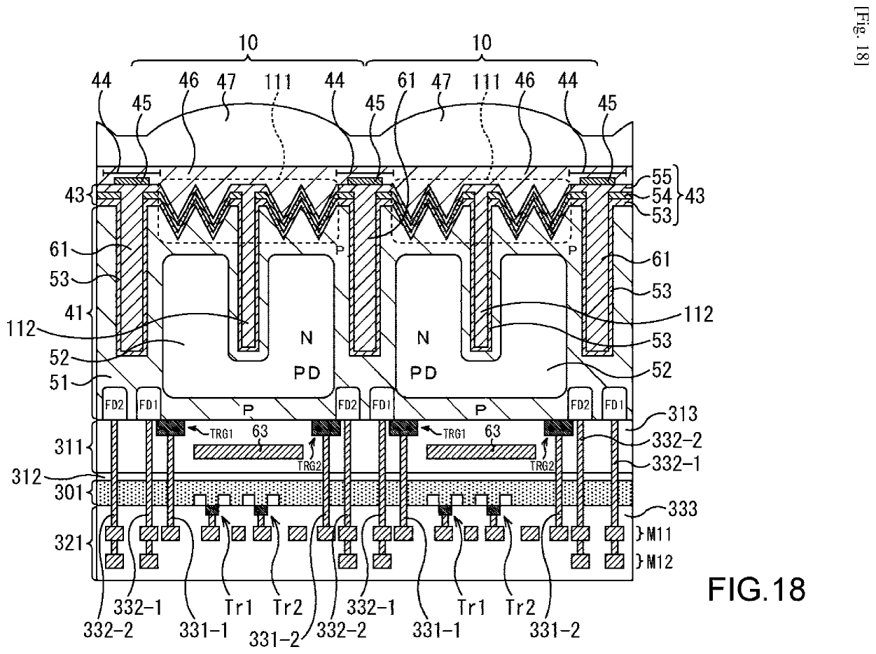

FIG. 18 is a cross-sectional view showing a seventh configuration example of the pixel 10.

In FIG. 18, portions corresponding to those of the first to sixth configuration examples described above will be denoted by the same reference symbols, and their descriptions will be appropriately omitted.

In the first to sixth configuration examples described above, the light-receiving element 1 includes one semiconductor substrate, that is, only the semiconductor substrate 41. However, in the seventh configuration example of FIG. 18, the light-receiving element 1 includes the two semiconductor substrates of the semiconductor substrate 41 and a semiconductor substrate 301. Hereinafter, the semiconductor substrate 41 and the semiconductor substrate 301 will also be called a first substrate 41 and a second substrate 301, respectively, in order to facilitate understanding.

The seventh configuration example of FIG. 18 is similar to the first configuration example of FIG. 2 in that the interpixel light-shielding film 45, the flattening film 46, and the on-chip lens 47 are formed on the light incident surface side of the first substrate 41. The seventh configuration example is also similar to the first configuration of FIG. 2 in that the interpixel trench portion 61 and the in-pixel trench portion 112 are formed up to a prescribed depth in the substrate depth direction from the rear surface side of the semiconductor substrate 41, and in that the moth-eye structure portion 111 is formed on the light incident surface of the semiconductor substrate 41.

Further, the seventh configuration example is also similar to the first configuration example in that the photodiode PD that is a photoelectric conversion unit is formed on a pixel-by-pixel basis, and in that the two transfer transistors TRG1 and TRG2 and the floating diffusion regions FD1 and FD2 that are charge accumulation units are formed on the front surface side of the first substrate 41.

On the other hand, the seventh configuration example is different from the first configuration example of FIG. 2 in that an insulating layer 313 of an interconnection layer 311 on the front surface side of the first substrate 41 is bonded to an insulating layer 312 of the second substrate 301.

In the interconnection layer 311 of the first substrate 41, at least one layer of the metal film M is included, and the light-shielding member 63 is formed by the metal film M in a region positioned under the forming region of the photodiode PD.

On the interface on a side opposite to the side of the insulating layer 312 that is the bonding surface side of the second substrate 301, the pixel transistors Tr1 and Tr2 are formed. The pixel transistors Tr1 and Tr2 are, for example, the amplification transistors AMP and the selection transistors SEL.

That is, in the first to sixth configuration examples includes only the one semiconductor substrate 41 (first substrate 41), all the pixel transistors of the transfer transistors TRG, the switching transistors FDG, the amplification transistors AMP, and the selection transistors SEL are formed on the semiconductor substrate 41. However, in the light-receiving element 1 of the seventh configuration example including the laminated structure of the two semiconductor substrates, pixel transistors other than the transfer transistors TRG, that is, the switching transistors FDG, the amplification transistors AMP, and the selection transistors SEL are formed on the second substrate 301.

On the side of the second substrate 301 that is opposite to the side of the first substrate 41, a multilayer interconnection layer 321 having at least the two layers of the metal films M is formed. The multilayer interconnection layer 321 includes a first metal film M11, a second metal film M12, and an interlayer insulating film 333.

The transfer drive signal TRG1g that controls the transfer transistor TRG1 is supplied from the first metal film M11 of the second substrate 301 to the gate electrode of the transfer transistor TRG1 of the first substrate 41 by a TSV (Through Silicon Via) 331-1 that penetrates the second substrate 301. The transfer drive signal TRG2g that controls the transfer transistor TRG2 is supplied from the first metal film M11 of the second substrate 301 to the gate electrode of the transfer transistor TRG2 of the first substrate 41 by a TSV 331-2 that penetrates the second substrate 301.

Similarly, charges accumulated in the floating diffusion region FD1 are transmitted from the side of the first substrate 41 to the first metal film M11 of the second substrate 301 by a TSV 332-1 that penetrates the second substrate 301. Charges accumulated in the floating diffusion region FD2 are also transmitted from the side of the first substrate 41 to the first metal film M11 of the second substrate 301 by a TSV 332-2 that penetrates the second substrate 301.

The interconnection capacity 64 is formed in the region (not shown) of the first metal film M11 or the second metal film M12. The metal film M in which the interconnection capacity 64 is formed is formed to have high interconnection density to form a capacity. The metal film M connected to the gate electrodes of the transfer transistors TRG, the switching transistors FDG, or the like is formed to have low interconnection density to reduce an induction current. Interconnection layers (metal films M) connected to the gate electrodes may be configured to be different depending on the pixel transistors.

As described above, the pixel 10 according to the seventh configuration example can include the two semiconductor substrates of the first substrate 41 and the second substrate 301 laminated with each other, and the pixel transistors other than the transfer transistors TRG are formed on the second substrate 301 different from the first substrate 41 having the photoelectric conversion part. Further, the vertical drive unit 22 and the pixel drive line 28 that control the drive of the pixel 10, the vertical signal line 29 that transmits a detection signal, or the like is also formed on the second substrate 301. Thus, the miniaturization of pixels can be achieved, and the degree of freedom in BEOL (Back End Of Line) design is also enhanced.

In the seventh configuration example as well, the pixel 10 has the interpixel trench portion 61 and the in-pixel trench portion 112 to prevent incident light from penetrating an adjacent pixel 10 while confining the same inside the own pixel and prevent the leakage of incident light from the adjacent pixel 10. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

In the manner described above, it is possible to further increase the amount of infrared light photoelectrically converted inside the semiconductor substrate 41 and improve quantum efficiency (QE), that is, sensitivity to the infrared light in the seventh configuration example as well.

Note that although the seventh configuration example of FIG. 18 has a configuration in which the first configuration example shown in FIG. 2 is replaced by a laminated structure in which two semiconductor substrates are laminated with each other, each of the second configuration example to the sixth configuration example described above may also similarly have a configuration in which the first configuration example shown in FIG. 2 is replaced by a laminated structure in which two semiconductor substrates are laminated with each other.

<13. First Configuration Example of IR Imaging Sensor>

The pixel structure having the interpixel trench portion 61 and the in-pixel trench portion 112 described above can be applied not only to a light-receiving element that outputs distance measurement information based an indirect ToF method but also to an IR imaging sensor that generates an IR image.

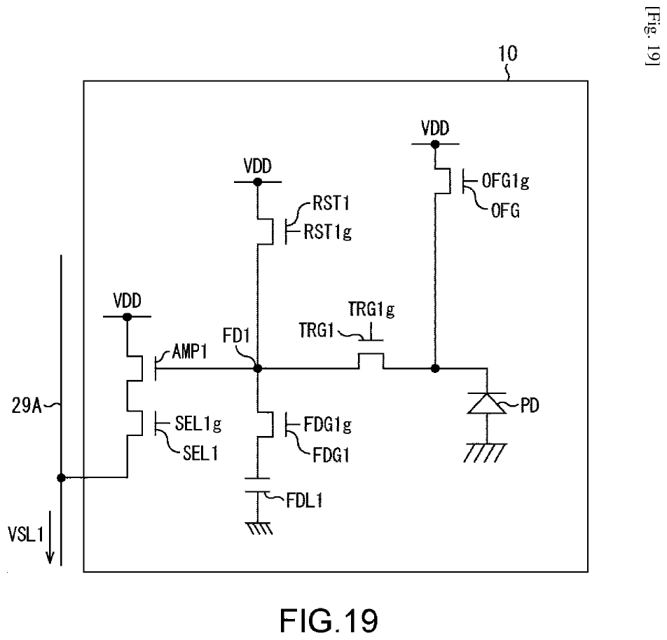

FIG. 19 shows the circuit configuration of the pixel 10 in a case in which the light-receiving element 1 includes an IR imaging sensor that generates and outputs an IR image.

In a case in which the light-receiving element 1 is a TOF sensor, charges generated by the photodiode PD are distributed to and accumulated in the two floating diffusion regions FD1 and FD2. Therefore, the pixel 10 has the two transfer transistors TRG, the two floating diffusion regions FD, the two additional capacitors FDL, the two switching transistors FDG, the two amplification transistors AMP, the two reset transistors RST, and the two selection transistors SEL.

In a case in which the light-receiving element 1 is an IR imaging sensor, a charge accumulation unit that temporarily retains charges generated by the photodiode PD may be provided alone. Therefore, each of the transfer transistor TRG, the floating diffusion region FD, the additional capacitor FDL, the switching transistor FDG, the amplification transistor AMP, the reset transistor RST, and the selection transistor SEL is also provided alone.

In other words, in a case in which the light-receiving element 1 is an IR imaging sensor, the configuration of the pixel 10 is equal to a configuration in which the transfer transistor TRG2, the switching transistor FDG2, the reset transistor RST2, the amplification transistor AMP2, and the selection transistor SEL2 are omitted from the circuit configuration shown in FIG. 4. The floating diffusion region FD2 and the vertical signal line 29B are also omitted.

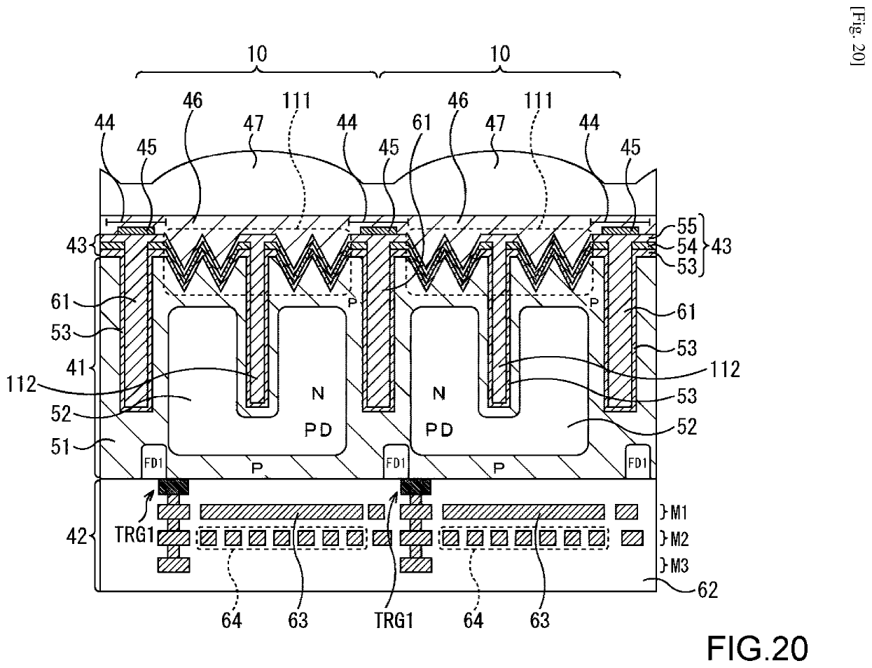

FIG. 20 is a cross-sectional view showing a first configuration example of the pixel 10 in a case in which the light-receiving element 1 includes an IR imaging sensor.

The difference between a case in which the light-receiving element 1 includes an IR imaging sensor and a case in which the light-receiving element 1 includes a ToF sensor is the presence or absence of the floating diffusion region FD2 and the pixel transistors formed on the front surface side of the semiconductor substrate 41 as described in FIG. 19. Therefore, the configuration of the multilayer interconnection layer 42 on the front surface side of the semiconductor substrate 41 is different from that of FIG. 2, but the configurations of the interpixel trench portion 61, the in-pixel trench portion 112, and the moth-eye structure portion 111 are similar to those of FIG. 2.

FIG. 20 shows a cross-sectional configuration in a case in which the first configuration example shown in FIG. 2 is applied to an IR imaging sensor. Similarly, the second configuration example to the sixth configuration example described above can also be applied to an IR imaging sensor in such a manner that the floating diffusion region FD2 and its corresponding pixel transistors formed on the front surface side of the semiconductor substrate 41 are omitted.

In a case in which the light-receiving element 1 includes an IR imaging sensor as well, the pixel 10 has the interpixel trench portion 61 and the in-pixel trench portion 112 to prevent incident light from penetrating an adjacent pixel 10 while confining the same inside the own pixel and prevent the leakage of incident light from the adjacent pixel 10. Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

Accordingly, in the first configuration example of the pixel 10 as well in a case in which the light-receiving element 1 includes an IR imaging sensor, it is possible to further increase the amount of infrared light photoelectrically converted inside the semiconductor substrate 41 and improve quantum efficiency (QE), that is, sensitivity to the infrared light.

<14. Second Configuration Example of IR Imaging Sensor>

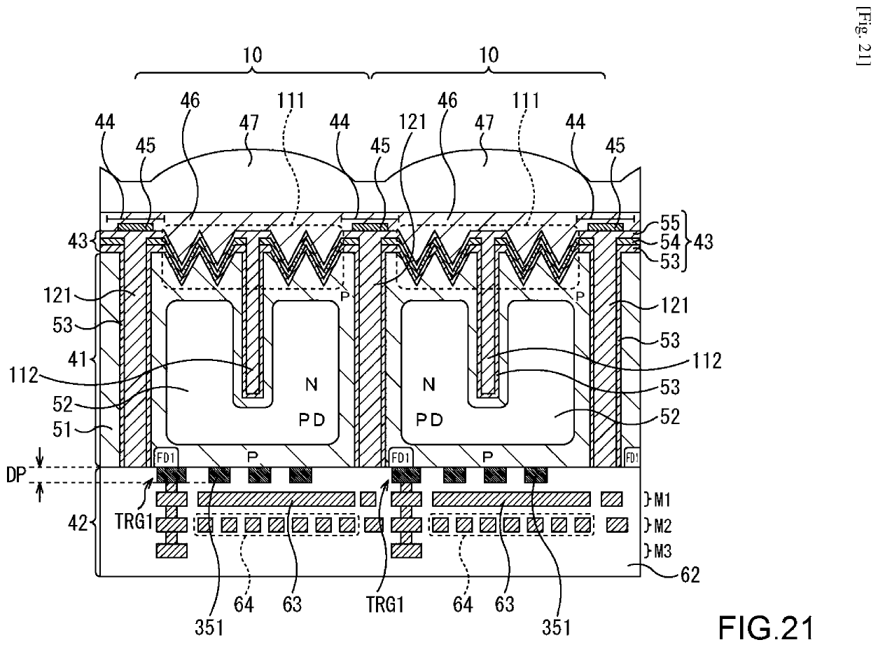

FIG. 21 is a cross-sectional view showing a second configuration example of the pixel 10 in a case in which the light-receiving element 1 includes an IR imaging sensor.

In FIG. 21, portions corresponding to those of other configuration examples described above will be denoted by the same reference symbols, and their descriptions will be appropriately omitted.

In the second configuration example of the IR imaging sensor of FIG. 21, the interpixel trench portion 61 formed at the pixel boundary portion 44 of the semiconductor substrate 41 in the first configuration example of the IR imaging sensor shown in FIG. 20 is replaced by the interpixel trench portion 121. The interpixel trench portion 121 is a trench portion that penetrates the semiconductor substrate 41 and similar to that of the second configuration example of the pixel 10 of the ToF sensor shown in FIG. 8.

With the formation of such an interpixel trench portion 121, it is possible to electrically completely separate adjacent pixels from each other. Thus, the interpixel trench portion 121 prevents incident light from penetrating an adjacent pixel 10 while confining the same inside the own pixel and prevents the leakage of incident light from the adjacent pixel 10.

Further, a diffusion film 351 regularly arranged at a prescribed interval is, for example, formed on the interface on the front surface side of the semiconductor substrate 41 that is a side on which the multilayer interconnection layer 42 is formed. The diffusion film 351 is made of the same material (for example, polysilicon) as that of the gate of the transfer transistor TRG1 at the same substrate depth position as that of the gate of the transfer transistor TRG1. Since the diffusion film 351 is made of the same material at the same substrate depth position as that of the gate of the transfer transistor TRG1, the diffusion film 351 can be formed simultaneously with the gate of the transfer transistor TRG1. Therefore, it is possible to standardize steps and reduce the number of the steps. The diffusion film 351 has a thickness of, for example, 100 nm or more and 500 nm or less. Note that the diffusion film 351 may be made of polysilicon and a salicide film and may be made of a material having polycrystalline silicon as its main ingredient. Further, although omitted in the figure, an insulating film (gate insulating film) is formed like the gate of the transfer transistor TRG1 between the diffusion film 351 and the interface of the semiconductor substrate 41.

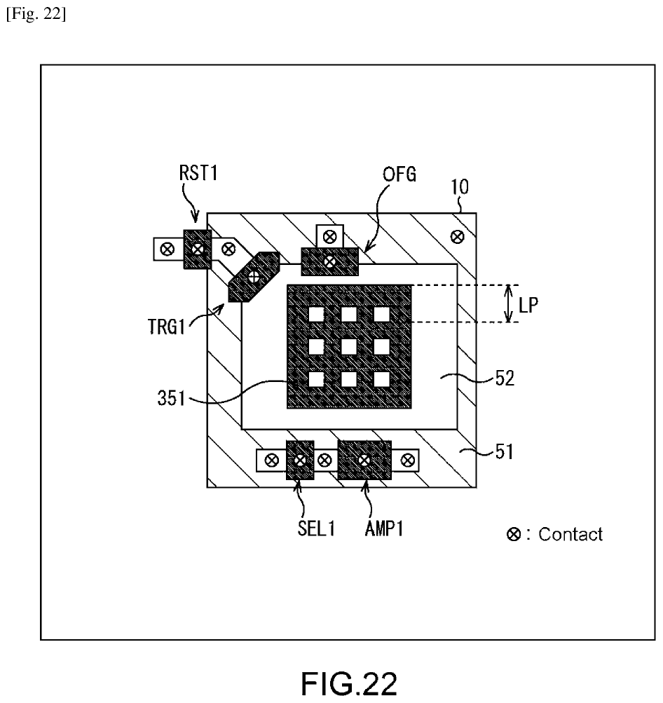

FIG. 22 is a plan view of the pixel 10 that shows the planar arrangement of the diffusion film 351 shown in FIG. 21. Note that FIG. 22 shows also the arrangement of the pixel transistors of the pixel 10.

In FIG. 22, a horizontal direction corresponds to the row direction (horizontal direction) of FIG. 1, and a vertical direction corresponds to the column direction (vertical direction) of FIG. 1.

As shown in FIG. 22, the diffusion film 351 has a two-dimensional periodic structure in which protrusion portions that are portions having a film of a prescribed line width and recessed portions that are portions having no film are repeatedly formed at a prescribed cycle LP in each of the row direction and the column direction. The cycle LP corresponding to a pitch at which the diffusion film 351 is formed is set at, for example, 200 nm or more and 1000 nm or less. The diffusion film 351 is formed into an island shape in the region of the central part of the rectangular pixel 10 and brought into a floating state in which the diffusion film 351 is not connected to other electrodes. Note that the diffusion film 351 may be connected to a prescribed electrode to have, for example, a ground potential (GND) or a negative bias instead of being brought into a floating state.

According to the second configuration example of FIGS. 21 and 22, the interpixel trench portion 121 and the in-pixel trench portion 112 are formed at the pixel boundary portion 44 and the central part of the pixel, respectively, to prevent incident light incident on the semiconductor substrate 41 from penetrating an adjacent pixel 10 while confining the same inside the own pixel and prevent the leakage of incident light from the adjacent pixel 10.

Further, the light-shielding member 63 is provided in the metal film M positioned under the forming region of the photodiode PD to cause infrared light, which has passed through the semiconductor substrate 41 without being photoelectrically converted inside the semiconductor substrate 41, to be reflected by the light-shielding member 63 and incident on the semiconductor substrate 41 again.

However, there is a possibility that light reflected by the light-shielding member 63 penetrates to the outside (the side of the on-chip lens 47) of the semiconductor substrate 41 when the light-shielding member 63 has high reflectance. In order to solve this problem, the diffusion film 351 having a two-dimensional irregularity structure is formed on the interface on the front surface of the semiconductor substrate 41. In this manner, light that penetrates to the multilayer interconnection layer 42 from the semiconductor substrate 41 and light reflected by the light-shielding member 63 are diffused by the diffusion film 351 to be prevented from penetrating to the side of the on-chip lens 47 of the semiconductor substrate 41.

Accordingly, it is possible to confine incident light, which has been temporarily incident on the semiconductor substrate 41 from the side of the on-chip lens 47, inside the semiconductor substrate 41 with high efficiency according to the second configuration example of the IR imaging sensor. That is, it is possible to further increase the amount of infrared light photoelectrically converted inside the semiconductor substrate 41 and improve quantum efficiency (QE), that is, sensitivity to the infrared light.

Note that the light-shielding member 63 is not necessarily provided but can be omitted when light is satisfactorily reflected and diffused to the semiconductor substrate 41 by the diffusion film 351.

<15. Third Configuration Example of IR Imaging Sensor>

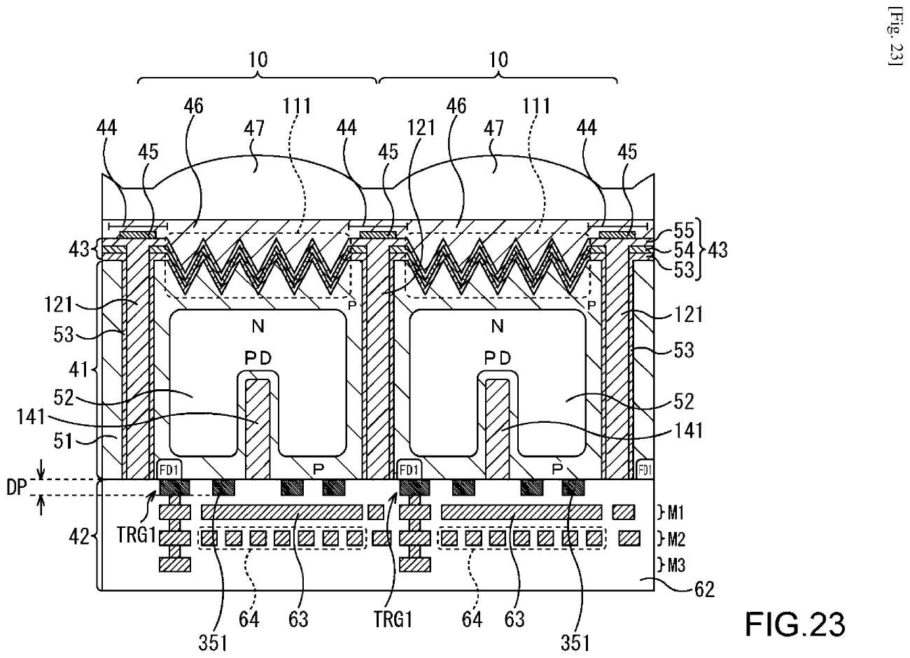

FIG. 23 is a cross-sectional view showing a third configuration example of the pixel 10 in a case in which the light-receiving element 1 includes an IR imaging sensor.

In FIG. 23, portions corresponding to those of other configuration examples described above will be denoted by the same reference symbols, and their descriptions will be appropriately omitted.

In the third configuration example of FIG. 23, the in-pixel trench portion 112 formed at the central part of the pixel of the moth-eye structure portion 111 in the second configuration example of FIG. 21 is replaced by the in-pixel trench portion 141 formed to be engraved up to a prescribed depth from the front surface side of the semiconductor substrate 41. Further, since the in-pixel trench portion 141 is formed on the front surface side of the semiconductor substrate 41, the diffusion film 351 is formed at a position at which the diffusion film 351 does not overlap the in-pixel trench portion 141. The in-pixel trench portion 141 is similar to that of the third configuration example of the pixel 10 of the ToF sensor shown in FIG. 9.

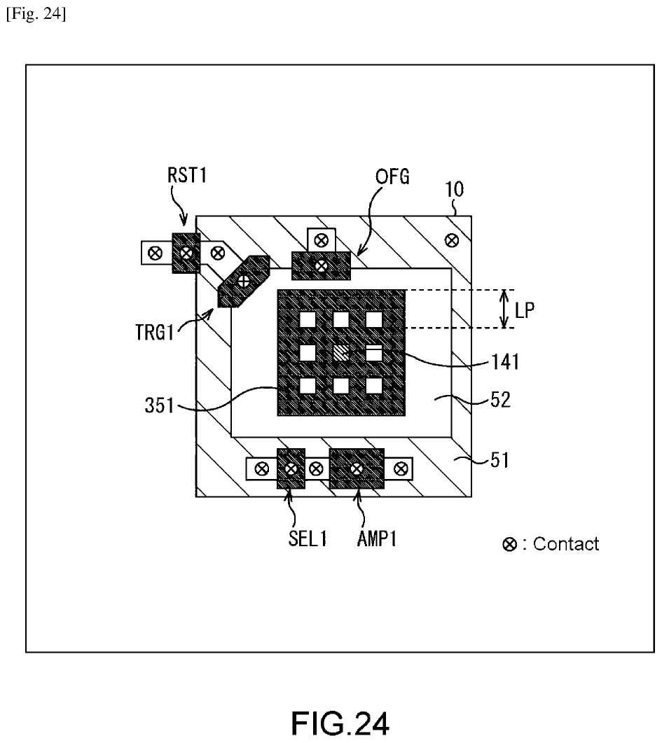

FIG. 24 is a plan view of the pixel 10 that shows the planar arrangement of the diffusion film 351 shown in FIG. 23.

As shown in FIG. 24, the diffusion film 351 is formed at a position at which the diffusion film 351 does not overlap the in-pixel trench portion 141.

Except for the point described above, the third configuration example of the IR imaging sensor is similar to the second configuration example of FIG. 21.

As described above with reference to FIG. 9, it is possible to increase the probability of confining incident light inside the own pixel when the in-pixel trench portion 141 is provided instead of the in-pixel trench portion 112. Further, the interpixel trench portion 121 is also formed at the pixel boundary portion 44 to prevent incident light incident on the semiconductor substrate 41 from penetrating an adjacent pixel 10 while confining the same inside the own pixel and prevent the leakage of incident light from the adjacent pixel 10. In addition, infrared light is prevented from penetrating to the side of the on-chip lens 47 of the semiconductor substrate 41 by the diffusion effect of the diffusion film 351.

Accordingly, it is possible to confine incident light, which has been temporarily incident on the semiconductor substrate 41 from the side of the on-chip lens 47, inside the semiconductor substrate 41 with high efficiency according to the third configuration example of the IR imaging sensor. That is, it is possible to further increase the amount of infrared light photoelectrically converted inside the semiconductor substrate 41 and improve quantum efficiency (QE), that is, sensitivity to the infrared light.

<16. Fourth Configuration Example of IR Imaging Sensor>

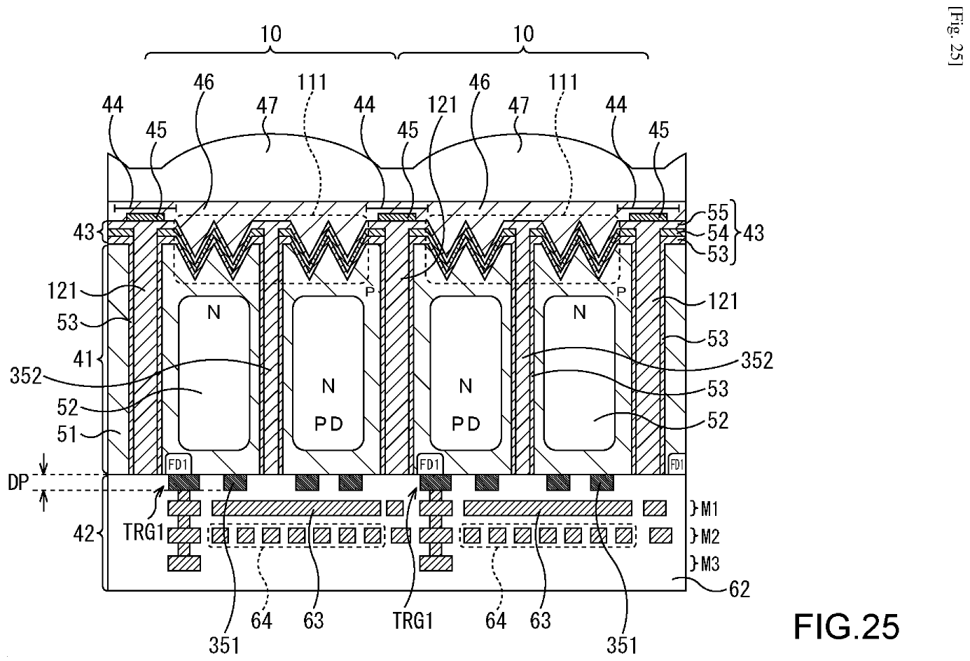

FIG. 25 is a cross-sectional view showing a fourth configuration example of the pixel 10 in a case in which the light-receiving element 1 includes an IR imaging sensor.

In FIG. 25, portions corresponding to those of other configuration examples described above will be denoted by the same reference symbols, and their descriptions will be appropriately omitted.

In the fourth configuration example of the IR imaging sensor of FIG. 25, the in-pixel trench portion 112 formed at the central part of the pixel of the semiconductor substrate 41 in the first configuration example of the IR imaging sensor shown in FIG. 20 is replaced by an in-pixel trench portion 352 that penetrates the semiconductor substrate 41. The in-pixel trench portion 352 is similar to the in-pixel trench portion 112 except that a trench portion is formed so as to penetrate from the rear surface side to the front surface side of the semiconductor substrate 41. Further, since the in-pixel trench portion 352 is formed to penetrate the front surface side of the semiconductor substrate 41, the diffusion film 351 is formed at a position at which the diffusion film 351 does not overlap the in-pixel trench portion 352.

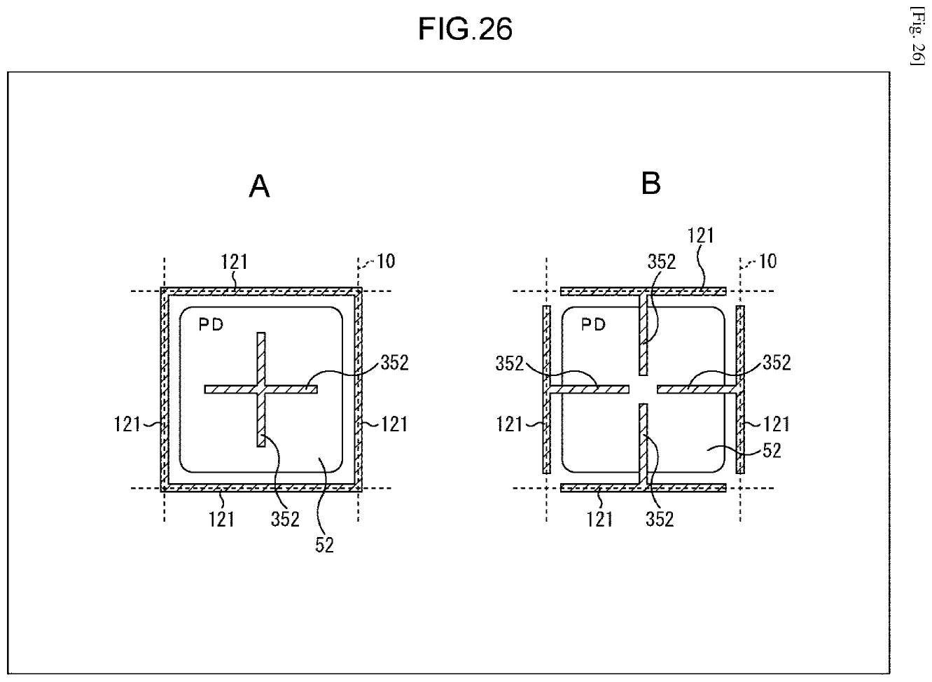

FIG. 26A is a plan view of the interpixel trench portion 121 and the in-pixel trench portion 352 of the pixel 10 according to the fourth configuration example of FIG. 25.

The in-pixel trench portion 352 is formed into a cross shape at the central part of the pixel inside the region of the photodiode PD.

In the cross-sectional view of FIG. 25, the photodiode PD is divided by the in-pixel trench portion 352. However, as shown in FIG. 26A, the in-pixel trench portion 352 does not extend to the boundary of the pixel in a plan direction. Therefore, the photodiode PD is formed by one region.

Note that the in-pixel trench portion 352 may be formed into a cross shape in which the in-pixel trench portion 352 does not cross at the central part of the pixel as shown in FIG. 26B. In this case as well, the photodiode PD is formed by one region.

Except for the point described above, the fourth configuration example of the IR imaging sensor is similar to the second configuration example of FIG. 21.

When the in-pixel trench portion 352 is provided instead of the in-pixel trench portion 112, it is also possible to increase the probability of confining incident light incident on the semiconductor substrate 41 inside the own pixel. Further, the interpixel trench portion 121 is also formed at the pixel boundary portion 44 to prevent incident light incident on the semiconductor substrate 41 from penetrating an adjacent pixel 10 while confining the same inside the own pixel and prevent the leakage of incident light from the adjacent pixel 10. In addition, infrared light is prevented from penetrating to the side of the on-chip lens 47 of the semiconductor substrate 41 by the diffusion effect of the diffusion film 351.

Accordingly, it is possible to confine incident light, which has been temporarily incident on the semiconductor substrate 41 from the side of the on-chip lens 47, inside the semiconductor substrate 41 with high efficiency according to the fourth configuration example of the IR imaging sensor. That is, it is possible to further increase the amount of infrared light photoelectrically converted inside the semiconductor substrate 41 and improve quantum efficiency (QE), that is, sensitivity to the infrared light.

<Modified Example of Diffusion Film 351>

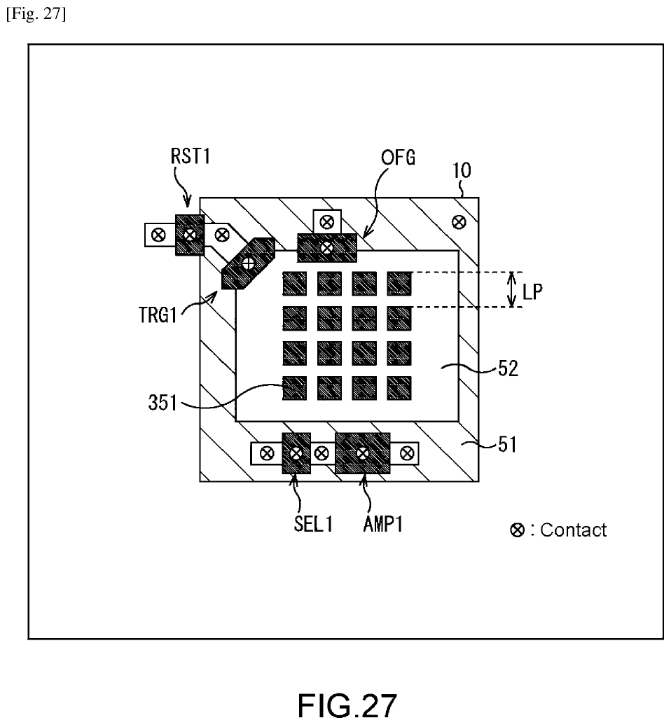

The diffusion film 351 shown in FIG. 22 or the like has a latticed planar shape in which the linear protrusion portions having a film of a prescribed line width cross each other. However, as shown in FIG. 27, the protrusion portions and the recessed portions of the diffusion film 351 may be inverted. In the diffusion film 351 of FIG. 27, the protrusion portions serving as film portions and the recessed portions having no film are formed by inverting the diffusion film 351 of FIG. 22. Thus, the recessed portions having no film are arranged in a lattice-shaped pattern, and the rectangular protrusion portions are arranged at a prescribed interval. The interval between the rectangular protrusion portions in each of the row direction and the column direction is set at a prescribed cycle LP.

Further, a moth-eye structure similar to the moth-eye structure portion 111 on the rear surface side may be formed on the interface on the front surface side of the semiconductor substrate 41, and the diffusion film 351 may be formed on the moth-eye structure. In this case, the diffusion film 351 does not have a gap pattern in which protrusion portions and recessed portions are repeatedly formed at the prescribed cycle LP in each of the row direction and the column direction but may be a film having a prescribed film thickness in which recessed portions are not formed (but only protrusion portions are formed).

<17. First Configuration Example of SPAD Pixel>

In the embodiments described above, the light-receiving element 1 is a ToF sensor that outputs distance measurement information based on an indirect ToF method in a case in which the light-receiving element 1 is a ToF sensor.

The ToF sensor employs a direct ToF method, besides the indirect ToF method. The indirect ToF method is a method in which a flying time until reflected light is received after the emission of irradiation light is detected as a phase difference to calculate a distance to an object. On the other hand, the direct ToF method is a method in which a flying time until reflected light is received after the emission of irradiation light is directly measured to calculate a distance to an object.

In the light-receiving element 1 based on the direct ToF method, SPADs (Single Photon Avalanche Diodes) or the like are, for example, used as the photoelectric conversion elements of the respective pixels 10.

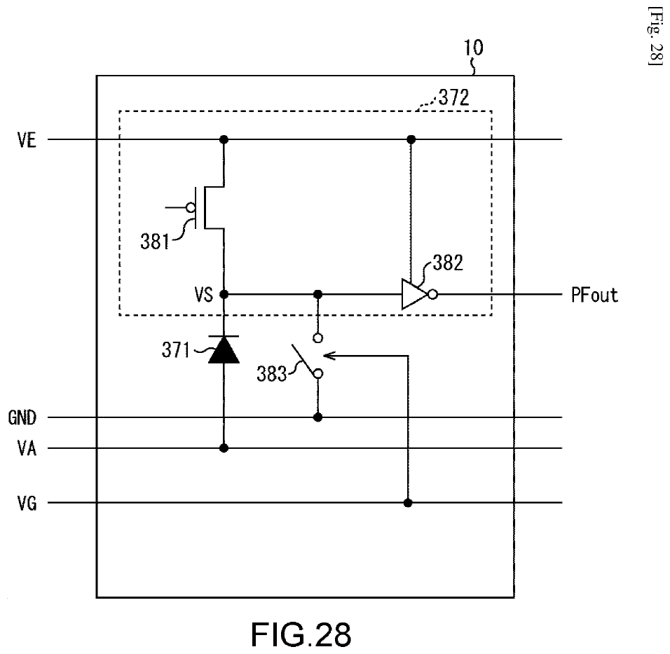

FIG. 28 shows a circuit configuration example in a case in which the pixel 10 is a SPAD pixel using a SPAD as a photoelectric conversion element.

The pixel 10 of FIG. 28 includes a SPAD 371 and a reading circuit 372 including a transistor 381 and an inverter 382. Further, the pixel 10 includes also a switch 383. The transistor 381 includes a P-type MOS transistor.

The cathode of the SPAD 371 is connected to the drain of the transistor 381 and connected to the input terminal of the inverter 382 and one end of the switch 383. The anode of the SPAD 371 is connected to a power supply voltage VA (also called an anode voltage VA below).

The SPAD 371 is a photodiode (single photon avalanche photodiode) that avalanche-multiplies generated electrons and outputs the signal of a cathode voltage VS when incident light is incident on the SPAD 371. The power supply voltage VA supplied to the anode of the SPAD 371 is, for example, a negative bias (negative potential) of about −20 V.

The transistor 381 is a constant current source that operates in a saturation region and serves as a quenching resistor to perform passive quenching. The source of the transistor 381 is connected to a power supply voltage VE, and the drain thereof is connected to the cathode of the SPAD 371, the input end of the inverter 382, and one end of the switch 383. Accordingly, the power supply voltage VE is also supplied to the cathode of the SPAD 371. Instead of the transistor 381 connected in series to the SPAD 371, a pull-up resistor can also be used.

A voltage (excess bias) greater than a breakdown voltage VBD of the SPAD 371 is applied to the SPAD 371 in order to detect light (photon) with sufficient efficiency. For example, when the breakdown voltage VBD of the SPAD 371 is 20 V and a voltage greater than the breakdown voltage VBD by 3 V is applied to the SPAD 371, the power supply voltage VE supplied to the source of the transistor 381 is 3 V.

Note that the breakdown voltage VBD of the SPAD 371 changes greatly with temperature or the like. Therefore, the voltage applied to the SPAD 371 is controlled (adjusted) according to a change in the breakdown voltage VBD. For example, when the power supply voltage VE is a fixed voltage, the anode voltage VA is controlled (adjusted).

One of both ends of the switch 383 is connected to the cathode of the SPAD 371, the input terminal of the inverter 382, and the drain of the transistor 381, and the other end thereof is connected to a ground (GND). The switch 383 can include an N-type MOS transistor and is turned on/off according to a gating control signal VG supplied from the vertical drive unit 22.

The vertical drive unit 22 supplies a High or Low gating control signal VG to the switch 383 of each pixel 10 and causes the switch 383 to be turned on or off to set each pixel 10 of the pixel array unit 21 as an active pixel or an inactive pixel. The active pixel is a pixel that detects the incidence of a photon, and the inactive pixel is a pixel that does not detect the incidence of a photon. When the switch 383 is turned on according to the gating control signal VG and the cathode of the SPAD 371 is controlled to be connected to the ground, the pixel 10 becomes an inactive pixel.

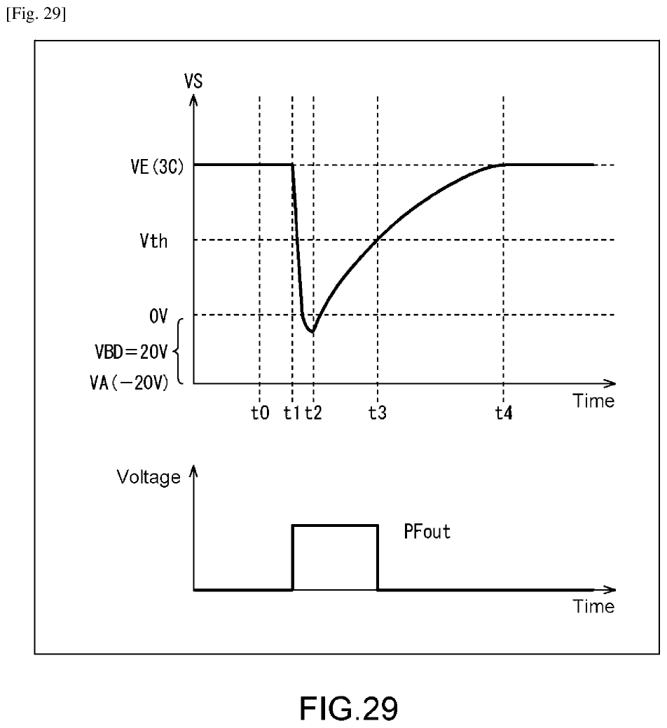

The operation of the pixel 10 in a case in which the pixel 10 of FIG. 28 is set as an active pixel will be described with reference to FIG. 29.

FIG. 29 is a graph showing a change in the cathode voltage VS of the SPAD 371 and a detection signal PFout according to the incidence of a photon.

First, when the pixel 10 is an active pixel, the switch 383 is set to be turned off as described above.

The power supply voltage VE (for example, 3 V) is supplied to the cathode of the SPAD 371, and the power supply voltage VA (for example, −20 V) is supplied to the anode thereof. Therefore, a reverse voltage greater than the breakdown voltage VBD (=20 V) is applied to the SPAD 371. As a result, the SPAD 371 is set in a Geiger mode. In this state, the cathode voltage VS of the SPAD 371 is the same as the power supply voltage VE as seen in, for example, time t0 of FIG. 29.

When a photon is incident on the SPAD 371 set in the Geiger mode, a current flows into the SPAD 371 with the occurrence of avalanche multiplication.

When a current flows into the SPAD 371 with the occurrence of avalanche multiplication at time t1 of FIG. 29, the current flows into the SPAD 371 after the time t1. Accordingly, the current flows also into the transistor 381, and a voltage drop occurs due to the resistance component of the transistor 381.

When the cathode voltage VS of the SPAD 371 becomes smaller than 0 V at time t2, the voltage between the anode and the cathode of the SPAD 371 becomes smaller than the breakdown voltage VBD. Therefore, the avalanche multiplication stops. Here, an operation in which the current generated by the avalanche multiplication flows into the transistor 381 to cause the occurrence of the voltage drop and the cathode voltage VS becomes smaller than the breakdown voltage VBD with the occurrence of the voltage drop to cause the stop of the avalanche multiplication is a quench operation.

When the avalanche multiplication stops, the current flowing into the resistor of the transistor 381 gradually reduces. As a result, the cathode voltage VS restores to the initial power supply voltage VE at time t4, which creates a state in which a next new photon can be detected (recharge operation).

The inverter 382 outputs an Lo detection signal PFout when the cathode voltage VS that is an input voltage is a prescribed threshold voltage Vth or more, and outputs a Hi detection signal PFout when the cathode voltage VS is less than the prescribed threshold voltage Vth. Accordingly, when a photon is incident on the SPAD 371 and the cathode voltage VS reduces with the occurrence of the avalanche multiplication and becomes smaller than the threshold voltage Vth, the detection signal PFout changes from a low level to a high level. On the other hand, when the avalanche multiplication of the SPAD 371 converges and the cathode voltage VS increases and becomes the threshold voltage Vth or more, the detection signal PFout changes from a high level to a low level.

Note that when the pixel 10 is an inactive pixel, the switch 383 is turned on. When the switch 383 is turned on, the cathode voltage of the SPAD 371 becomes 0 V. As a result, the voltage between the anode and the cathode of the SPAD 371 becomes the breakdown voltage VBD or less. Therefore, the SPAD 371 does not react even when a photon enters the SPAD 371.

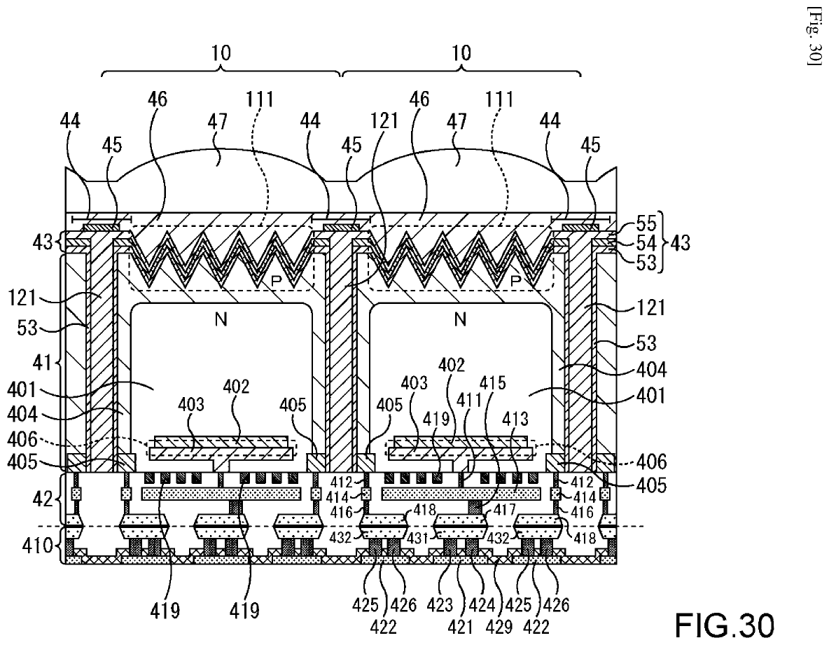

FIG. 30 is a cross-sectional view showing a first configuration example in a case in which the pixel 10 is a SPAD pixel.

In FIG. 30, portions corresponding to those of other configuration examples described above will be denoted by the same reference symbols, and their descriptions will be appropriately omitted.

A pixel region inside the interpixel trench portion 121 of the semiconductor substrate 41 includes an N-well region 401, a P-type diffusion layer 402, an N-type diffusion layer 403, a hole accumulation layer 404, and a concentrated P-type diffusion layer 405. Further, an avalanche multiplication region 406 is formed by a depletion layer formed in a region in which the P-type diffusion layer 402 and the N-type diffusion layer 403 are connected to each other.

The N-well region 401 is formed when the impurity concentration of the semiconductor substrate 41 is controlled to be n-type, and forms an electric field to transfer electrons generated by the photoelectric conversion of the pixel 10 to the avalanche multiplication region 406.

The P-type diffusion layer 402 is a concentrated P-type diffusion layer (P+) formed to extend over almost the whole surface of a pixel region in a plan direction. The N-type diffusion layer 403 is a concentrated N-type diffusion layer (N+) that is positioned in the vicinity of the front surface of the semiconductor substrate 41 and formed to extend over almost the whole surface of the pixel region like the P-type diffusion layer 402. The N-type diffusion layer 403 is a contact layer that is connected to a contact electrode 411 serving as a cathode electrode to supply a negative voltage for forming the avalanche multiplication region 406, and that has a protrusion shape so as to be formed to partially extend to the contact electrode 411 of the front surface of the semiconductor substrate 41. The power supply voltage VE is applied to the N-type diffusion layer 403 from the contact electrode 411.

The hole accumulation layer 404 is a P-type diffusion layer (P) formed to surround the lateral surface and the bottom surface of the N-well region 401, and accumulates holes. Further, the hole accumulation layer 404 is connected to the concentrated P-type diffusion layer 405 electrically connected to a contact electrode 412 serving as the anode electrode of the SPAD 371.

The concentrated P-type diffusion layer 405 is a concentrated P-type diffusion layer (P++) formed to surround the outer periphery in the plan direction of the N-well region 401 in the vicinity of the front surface of the semiconductor substrate 41, and constitutes a contact layer for electrically connecting the hole accumulation layer 404 and the contact electrode 412 of the SPAD 371 to each other. The power supply voltage VA is applied to the concentrated P-type diffusion layer 405 from the contact electrode 412.

Note that a P-well region in which the impurity concentration of the semiconductor substrate 41 is controlled to be P-type may be formed instead of the N-well region 401. Note that when the P-well region is formed instead of the N-well region 401, the power supply voltage VA and the power supply voltage VE are applied to the N-type diffusion layer 403 and the concentrated P-type diffusion layer 405, respectively.

In the multilayer interconnection layer 42, contact electrodes 411 and 412, metal interconnections 413 and 414, contact electrodes 415 and 416, metal pads 417 and 418, and a diffusion film 419 are formed.

The diffusion film 419 is similar to the diffusion film 351 formed in the pixel 10 of FIG. 21 or the like. That is, the diffusion film 419 is regularly arranged at, for example, a prescribed interval on the interface on the front surface side of the semiconductor substrate 41 that is a side on which the multilayer interconnection layer 42 is formed, and light that penetrates to the multilayer interconnection layer 42 from the semiconductor substrate 41 and light reflected by the metal interconnection 413 are diffused by the diffusion film 419 to be prevented from further penetrating to the outside (the side of the on-chip lens 47) of the semiconductor substrate 41.

Further, the multilayer interconnection layer 42 is bonded to an interconnection layer 410 of a logic circuit board (called a logic interconnection layer 410 below) in which logic circuits are formed. In the logic circuit board, the reading circuit 372, a MOS transistor serving as the switch 383, and the like described above are formed.

The contact electrode 411 connects the N-type diffusion layer 403 and the metal interconnection 413 to each other, and the contact electrode 412 connects the concentrated P-type diffusion layer 405 and the metal interconnection 414 to each other.

As shown in FIG. 30, the metal interconnection 413 is formed to be wider than the avalanche multiplication region 406 so as to cover at least the avalanche multiplication region 406 in the plan direction. Further, the metal interconnection 413 causes light, which has passed through the semiconductor substrate 41, to be reflected to the semiconductor substrate 41.

As shown in FIG. 30, the metal interconnection 414 is formed to be positioned on the outer periphery of the metal interconnection 413 and overlap the concentrated P-type diffusion layer 405 in the plan direction.

The contact electrode 415 connects the metal interconnection 413 and the metal pad 417 to each other, and the contact electrode 416 connects the metal interconnection 414 and the metal pad 418 to each other.

The metal pads 417 and 418 and the metal pads 431 and 432 formed in the logic interconnection layer 410 are electrically and mechanically connected to each other by metal bonding through their metals (Cu).

In the logic interconnection layer 410, electrode pads 421 and 422, contact electrodes 423 to 426, an insulating layer 429, and metal pads 431 and 432 are formed.

Each of the electrode pads 421 and 433 is used to be connected to a logic circuit board (not shown), and the insulating layer 429 insulates the electrode pads 421 and 422 from each other.

The contact electrodes 423 and 424 connect the electrode pad 421 and the metal pad 431 to each other, and the contact electrodes 425 and 426 connect the electrode pad 422 and the metal pad 432 to each other.

The metal pad 431 is bonded to the metal pad 417, and the metal pad 432 is bonded to the metal pad 418.

By such an interconnection structure, the electrode pad 421 is, for example, connected to the N-type diffusion layer 403 via the contact electrodes 423 and 424, the metal pad 431, the metal pad 417, the contact electrode 415, the metal interconnection 413, and the contact electrode 411. Accordingly, in the pixel 10 of FIG. 30, the power supply voltage VE applied to the N-type diffusion layer 403 can be supplied from the electrode pad 421 of the logic circuit board.

Further, the electrode pad 422 is connected to the concentrated P-type diffusion layer 405 via the contact electrodes 425 and 426, the metal pad 432, the metal pad 418, the contact electrode 416, the metal interconnection 414, and the contact electrode 412. Accordingly, in the pixel 10 of FIG. 30, the anode voltage VA applied to the hole accumulation layer 404 can be supplied from the electrode pad 422 of the logic circuit board.

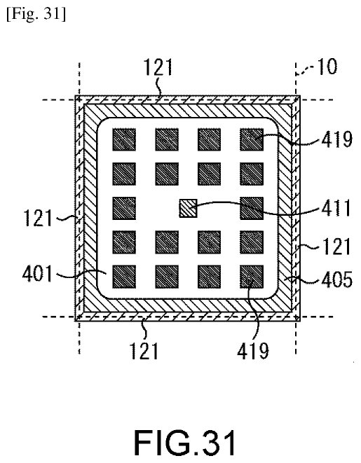

FIG. 31 is a plan view of a SPAD pixel that shows the planar arrangement of the diffusion film 419 shown in FIG. 30.

As shown in FIG. 31, the diffusion film 419 is formed in a region in which the diffusion film 419 overlaps the avalanche multiplication region 406 (not shown in FIG. 31) and at a position at which the diffusion film 419 does not overlap the contact electrode 411 serving as a cathode electrode.

The diffusion film 419 of FIG. 31 shows an example of a planar shape in which rectangular protrusion portions are arranged at a prescribed interval like the diffusion film 351 shown in FIG. 27. However, the diffusion film 419 may have, of course, a latticed planar shape like the diffusion film 351 of FIG. 22.

In the first configuration example of the SPAD pixel configured as described above, the interpixel trench portion 121 is formed at the pixel boundary portion 44, and the diffusion film 419 is formed on the interface on the front surface side of the semiconductor substrate 41 that is a side on which the multilayer interconnection layer 42 is formed.

Accordingly, it is possible to confine incident light, which has been temporarily incident on the semiconductor substrate 41 from the side of the on-chip lens 47, inside the semiconductor substrate 41 with high efficiency according to the first configuration example of the SPAD pixel. That is, it is possible to further increase the amount of infrared light photoelectrically converted inside the semiconductor substrate 41 and improve quantum efficiency (QE), that is, sensitivity to the infrared light.

<18. Second Configuration Example of SPAD Pixel>

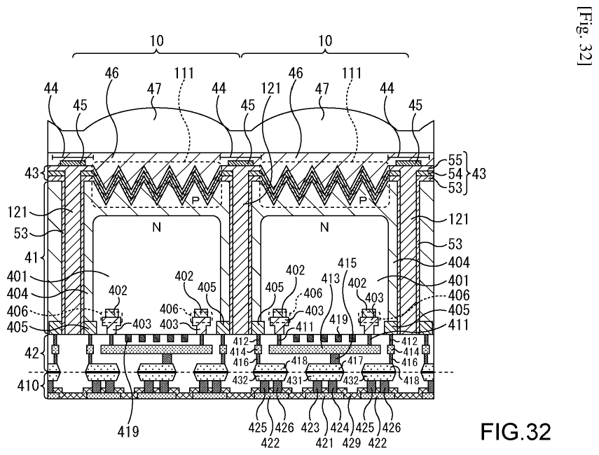

FIG. 32 is a cross-sectional view showing a second configuration example in a case in which the pixel 10 is a SPAD pixel.

In FIG. 32, portions corresponding to those of the first configuration example of the SPAD pixel shown in FIG. 30 will be denoted by the same reference symbols, and their descriptions will be appropriately omitted.

In the first configuration example of the SPAD pixel shown in FIG. 30, the P-type diffusion layer 402, the N-type diffusion layer 403, and the avalanche multiplication region 406 are formed at the central part of the pixel 10 that is almost the same as the planar region of the metal interconnection 413 in the plan direction, and the contact electrode 411 is also formed at the central part of the pixel 10.

On the other hand, in the second configuration example of the SPAD pixel of FIG. 32, the P-type diffusion layer 402, the N-type diffusion layer 403, and the avalanche multiplication region 406 are formed in a peripheral region close to the outer peripheral part of the metal interconnection 413 in the plan direction. The contact electrode 411 is also arranged in the vicinity of the periphery of the pixel 10 according to the position of the N-type diffusion layer 403.

The diffusion film 419 is regularly arranged at a prescribed interval on the interface on the front surface side of the semiconductor substrate 41 and on an inner side in the plan direction than the P-type diffusion layer 402, the N-type diffusion layer 403, and the avalanche multiplication region 406. The diffusion film 419 may also be made of a material such as polysilicon having polycrystalline silicon as its main ingredient.

It is also possible to confine incident light, which has been temporarily incident on the semiconductor substrate 41 from the side of the on-chip lens 47, inside the semiconductor substrate 41 with high efficiency with the interpixel trench portion 121 and the diffusion film 419 in the second configuration example of the SPAD pixel configured as described above. That is, it is possible to further increase the amount of infrared light photoelectrically converted inside the semiconductor substrate 41 and improve quantum efficiency (QE), that is, sensitivity to the infrared light.

<19. Third Configuration Example of SPAD Pixel>

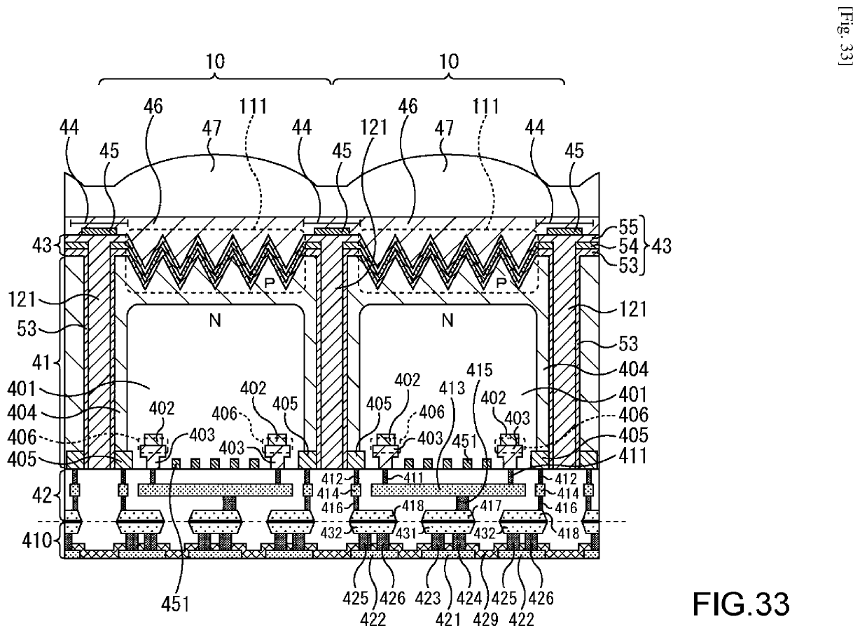

FIG. 33 is a cross-sectional view showing a third configuration example in a case in which the pixel 10 is a SPAD pixel.

In FIG. 33, portions corresponding to those of the second configuration example of the SPAD pixel shown in FIG. 32 will be denoted by the same reference symbols, and their descriptions will be appropriately omitted.

The third configuration example of the SPAD pixel of FIG. 33 is similar to the second configuration example of the SPAD pixel shown in FIG. 32 except that the diffusion film 419 in the second configuration example of the SPAD pixel shown in FIG. 32 is replaced by a diffusion film 451.

In the second configuration example of the SPAD pixel shown in FIG. 32, the diffusion film 419 is formed on the surface on the front surface side of the semiconductor substrate 41 via a gate insulating film (not shown) like the gate electrode of the pixel transistor using, for example, polysilicon or the like as a material.

On the other hand, the diffusion film 451 is formed to be embedded in the semiconductor substrate 41 by STI (Shallow Trench Isolation) that is a CMOS transistor separation structure. A material embedded as the diffusion film 451 is, for example, an insulating film such as SiO₂. The diffusion film 451 has a depth (thickness) of, for example 100 nm or more and 500 nm or less like the diffusion film 351. Further, the diffusion film 451 can have a planar shape similar to that of the diffusion film 351 shown in FIGS. 22 and 27.

It is also possible to confine incident light, which has been temporarily incident on the semiconductor substrate 41 from the side of the on-chip lens 47, inside the semiconductor substrate 41 with high efficiency with the interpixel trench portion 121 and the diffusion film 451 in the third configuration example of the SPAD pixel configured as described above. That is, it is possible to further increase the amount of infrared light photoelectrically converted inside the semiconductor substrate 41 and improve quantum efficiency (QE), that is, sensitivity to the infrared light.

<20. Configuration Example of CAPD Pixel>

In the embodiments described above, the pixels 10 according to the first to seventh configuration examples shown in FIGS. 1 to 18 in a case in which the light-receiving element 1 is an indirect ToF sensor are ToF sensors called sensors based on a gate method in which the charges of the photodiode PD are alternately applied as pulses to the two gates (transfer transistors TRG).

On the other hand, there is a ToF sensor called a sensor based on a CAPD (Current Assisted Photonic Demodulator) method in which a voltage is directly applied to the semiconductor substrate 41 of the ToF sensor to generate a current inside the substrate and a wide region inside the substrate is modulated at a high speed to distribute photoelectrically-converted charges.

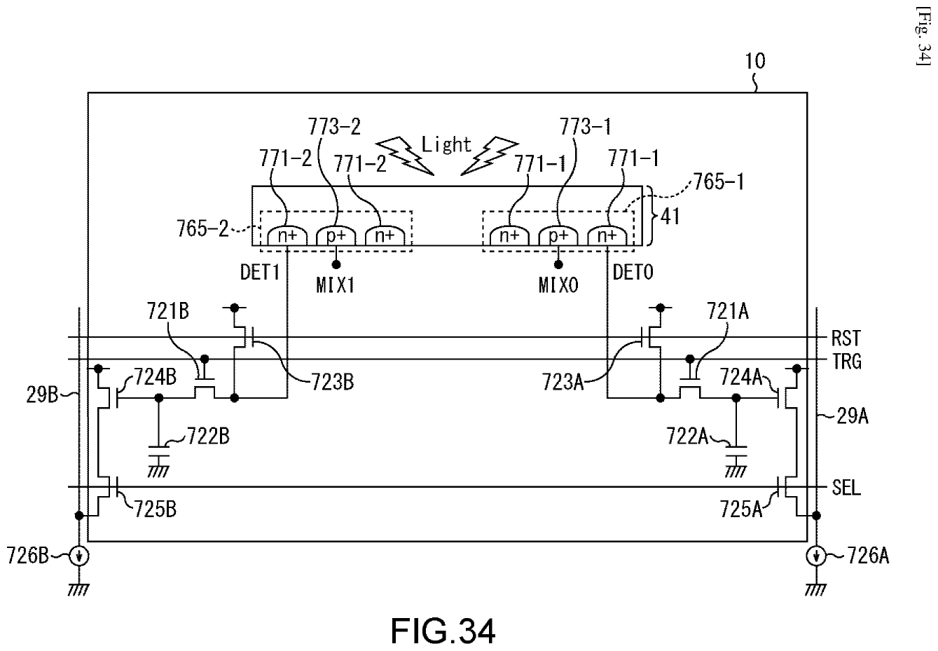

FIG. 34 shows a circuit configuration example in a case in which the pixel 10 is a CAPD pixel employing the CAPD method.

The pixel 10 of FIG. 34 has signal extraction units 765-1 and 765-2 inside the semiconductor substrate 41. The signal extraction unit 765-1 includes at least an N+ semiconductor region 77 that is an N-type semiconductor region and a P+ semiconductor region 773-1 that is a P-type semiconductor region. The signal extraction unit 765-2 includes at least an N+ semiconductor region 771-2 that is an N-type semiconductor region and a P+ semiconductor region 773-2 that is a P-type semiconductor region.

The pixel 10 has a transfer transistor 721A, a FD 722A, a reset transistor 723A, an amplification transistor 724A, and a selection transistor 725A with respect to the signal extraction unit 765-1.

Further, the pixel 10 has a transfer transistor 721B, a FD 722B, a reset transistor 723B, an amplification transistor 724B, and a selection transistor 725B with respect to the signal extraction unit 765-2.

The vertical drive unit 22 applies a prescribed voltage MIX0 (first voltage) to the P+ semiconductor region 773-1 and applies a prescribed voltage MIX1 (second voltage) to the P+ semiconductor region 773-2. For example, one of the voltages MIX0 and MIX1 is set at 1.5 V, and the other thereof is set at 0 V. The P+ semiconductor regions 773-1 and 773-2 are voltage application units to which the first voltage or the second voltage is applied.

The N+ semiconductor regions 771-1 and 771-2 are charge detection units that detect and accumulate charges generated when light incident on the semiconductor substrate 41 is photoelectrically converted.

When a transfer drive signal TRG that is supplied to the gate electrode of the transfer transistor 721A is brought into an active state, the transfer transistor 721A is brought into a conductive state correspondingly and transfers charges accumulated in the N+ semiconductor region 771-1 to the FD 722A. When the transfer drive signal TRG that is supplied to the gate electrode of the transfer transistor 721B is brought into an active state, the transfer transistor 721B is brought into a conductive state correspondingly and transfers charges accumulated in the N+ semiconductor region 771-2 to the FD 722B.

The FD 722A temporarily retains the charges supplied from the N+ semiconductor region 771-1. The FD 722B temporarily retains the charges supplied from the N+ semiconductor region 771-2.

When a reset drive signal RST that is supplied to the gate electrode of the reset transistor 723A is brought into an active state, the reset transistor 723A is brought into a conductive state correspondingly and resets the potential of the FD 722A to a prescribed level (reset voltage VDD). When the reset drive signal RST that is supplied to the gate electrode of the reset transistor 723B is brought into an active state, the reset transistor 723B is brought into a conductive state correspondingly and resets the potential of the FD 722B to a prescribed level (reset voltage VDD). Note that when the reset transistors 723A and 723B are brought into an active state, the transfer transistors 721A and 721B are also simultaneously brought into an active state.

When the source electrode of the amplification transistor 724A is connected to a vertical signal line 29A via the selection transistor 725A, the amplification transistor 724A constitutes a source follower circuit with a load MOS of a constant current source circuit unit 726A connected to one end of the vertical signal line 29A. When the source electrode of the amplification transistor 724B is connected to a vertical signal line 29B via the selection transistor 725B, the amplification transistor 724B constitutes a source follower circuit with a load MOS of a constant current source circuit unit 726B connected to one end of the vertical signal line 29B.

The selection transistor 725A is connected between the source electrode of the amplification transistor 724A and the vertical signal line 29A. When a selection drive signal SEL that is supplied to the gate electrode of the selection transistor 725A is brought into an active state, the selection transistor 725A is brought into a conductive state correspondingly and outputs a pixel signal output from the amplification transistor 724A to the vertical signal line 29A.

The selection transistor 725B is connected between the source electrode of the amplification transistor 724B and the vertical signal line 29B. When the selection drive signal SEL that is supplied to the gate electrode of the selection transistor 725B is brought into an active state, the selection transistor 725B is brought into a conductive state correspondingly and outputs a pixel signal output from the amplification transistor 724B to the vertical signal line 29B.

The transfer transistors 721A and 721B, the reset transistors 723A and 723B, the amplification transistors 724A and 724B, and the selection transistors 725A and 725B of the pixel 10 are controlled by, for example, the vertical drive unit 22.

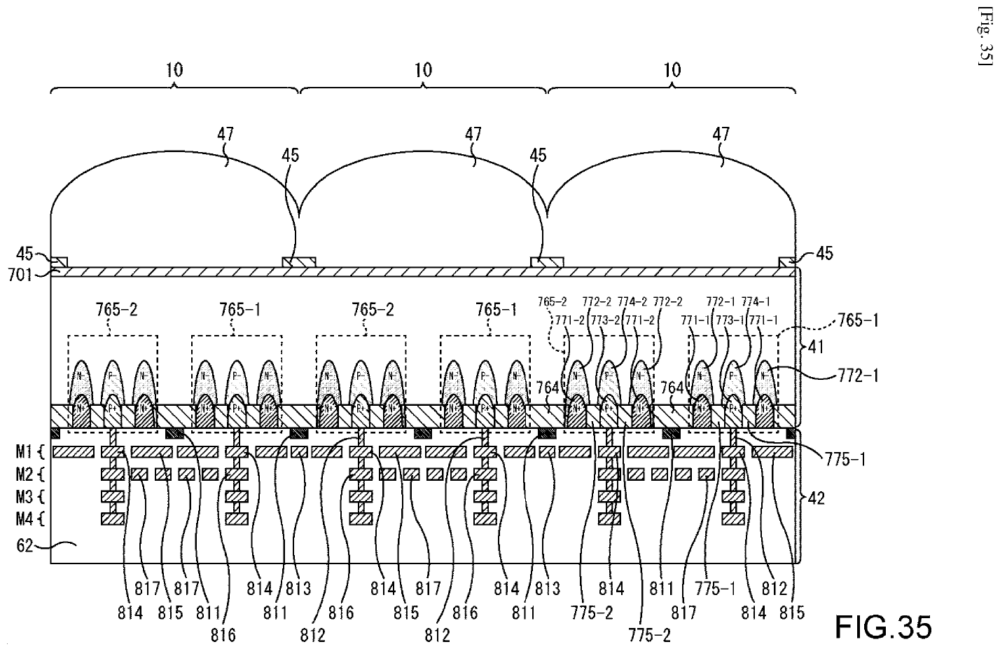

FIG. 35 is a cross-sectional view in a case in which the pixel 10 is a CAPD pixel.

In FIG. 35, portions corresponding to those of other configuration examples described above will be denoted by the same reference symbols, and their descriptions will be appropriately omitted.

In a case in which the pixel 10 is a CAPD pixel, an oxide film 764 is formed at the central portion of the pixel 10 in the vicinity of a surface on a side opposite to the side of the light incident surface of the semiconductor substrate 41 on which the on-chip lens 47 is formed, and the signal extraction units 765-1 and 765-2 are formed at both ends of the oxide film 764, respectively.

The signal extraction unit 765-1 has the N+ semiconductor region 771-1 that is an N-type semiconductor region, an N− semiconductor region 772-1 in which the concentration of donor impurities is lower than that of the N+ semiconductor region 771-1, the P+ semiconductor region 773-1 that is a P-type semiconductor region, and a P− semiconductor region 774-1 in which the concentration of acceptor impurities is lower than that of the P+ semiconductor region 773-1. With respect to Si, examples of the donor impurities include elements such as phosphorous (P) and arsenic (As) belonging to Group 5 in the periodic table of elements. With respect to Si, examples of the acceptor impurities include elements such as boron (B) belonging to Group 3 in the periodic table of elements. An element that becomes a donor impurity is called a donor element, and an element that becomes an acceptor impurity is called an acceptor element.

In the signal extraction unit 765-1, the N+ semiconductor region 771-1 and the N− semiconductor region 772-1 are formed around the P+ semiconductor region 773-1 and the P− semiconductor region 774-1 so as to surround the peripheries of the P+ semiconductor region 773-1 and the P− semiconductor region 774-1. The P+ semiconductor region 773-1 and the N+ semiconductor region 771-1 are in contact with the multilayer interconnection layer 42. The P− semiconductor region 774-1 is arranged on the P+ semiconductor region 773-1 (on the side of the on-chip lens 47) so as to cover the P+ semiconductor region 773-1, and the N− semiconductor region 772-1 is arranged on the N+ semiconductor region 771-1 (on the side of the on-chip lens 47) so as to cover the N+ semiconductor region 771-1. In other words, the P+ semiconductor region 773-1 and the N+ semiconductor region 771-1 are arranged on the side of the multilayer interconnection layer 42 inside the semiconductor substrate 41, and the N− semiconductor region 772-1 and the P− semiconductor region 774-1 are arranged on the side of the on-chip lens 47 inside the semiconductor substrate 41. Further, an isolation portion 775-1 made of an oxide film or the like is formed between the N+ semiconductor region 771-1 and the P+ semiconductor region 773-1 to isolate the regions from each other.

Similarly, the signal extraction unit 765-2 has the N+ semiconductor region 771-2 that is an N-type semiconductor region, an N− semiconductor region 772-2 in which the concentration of donor impurities is lower than that of the N+ semiconductor region 771-2, the P+ semiconductor region 773-2 that is a P-type semiconductor region, and a P− semiconductor region 774-2 in which the concentration of acceptor impurities is lower than that of the P+ semiconductor region 773-2.

In the signal extraction unit 765-2, the N+ semiconductor region 771-2 and the N− semiconductor region 772-2 are formed around the P+ semiconductor region 773-2 and the P− semiconductor region 774-2 so as to surround the peripheries of the P+ semiconductor region 773-2 and the P− semiconductor region 774-2. The P+ semiconductor region 773-2 and the N+ semiconductor region 771-2 are in contact with the multilayer interconnection layer 42. The P− semiconductor region 774-2 is arranged on the P+ semiconductor region 773-2 (on the side of the on-chip lens 47) so as to cover the P+ semiconductor region 773-2, and the N− semiconductor region 772-2 is arranged on the N+ semiconductor region 771-2 (on the side of the on-chip lens 47) so as to cover the N+ semiconductor region 771-2. In other words, the P+ semiconductor region 773-2 and the N+ semiconductor region 771-2 are arranged on the side of the multilayer interconnection layer 42 inside the semiconductor substrate 41, and the N− semiconductor region 772-1 and the P− semiconductor region 774-2 are arranged on the side of the on-chip lens 47 inside the semiconductor substrate 41. Further, an isolation portion 775-2 made of an oxide film or the like is formed between the N+ semiconductor region 771-2 and the P+ semiconductor region 773-2 to isolate the regions from each other.

The oxide film 764 is also formed in the region between the N+ semiconductor region 771-1 of the signal extraction unit 765-1 of a prescribed pixel 10 and the N+ semiconductor region 771-2 of the signal extraction unit 765-2 of an adjacent pixel 10 that is the boundary region between the pixels 10 adjacent to each other.

On the interface on the light incident surface side of the semiconductor substrate 41, a P+ semiconductor region 701 that has a laminated film having a positive fixed charge to cover the whole light incident surface is formed.

Hereinafter, the signal extraction units 765-1 and 765-2 will simply be called signal extraction units 765 when there is no need to particularly distinguish the signal extraction units 765-1 and 765-2 from each other.

Further, hereinafter, the N+ semiconductor regions 771-1 and 771-2 will simply be called N+ semiconductor regions 771 when there is no need to particularly distinguish the N+ semiconductor regions 771-1 and 771-2 from each other, and the N− semiconductor regions 772-1 and 772-2 will simply be called N− semiconductor regions 772 when there is no need to particularly distinguish the N− semiconductor regions 772-1 and 772-2 from each other.

In addition, hereinafter, the P+ semiconductor regions 773-1 and 773-2 will simply be called P+ semiconductor regions 773 when there is no need to particularly distinguish the P+ semiconductor regions 773-1 and 773-2 from each other, and the P− semiconductor regions 774-1 and 774-2 will simply be called P− semiconductor regions 774 when there is no need to particularly distinguish the P− semiconductor regions 774-1 and 774-2 from each other. Further, the isolation portions 775-1 and 775-2 will simply be called isolation portions 775 when there is no need to particularly distinguish the isolation portions 775-1 and 775-2 from each other.

The N+ semiconductor regions 771 provided in the semiconductor substrate 41 function as charge detection units that detect the amount of light incident on the pixel 10 from an outside, that is, the amount of signal carriers generated by the photoelectric conversion of the semiconductor substrate 41. Note that besides the N+ semiconductor regions 771, the N− semiconductor regions 772 in which the concentration of donor impurities is low may also be recognized as the charge detection units. Further, the P+ semiconductor regions 773 function as voltage application units that inject a multiplicity of carrier currents to the semiconductor substrate 41, that is, directly apply a voltage to the semiconductor substrate 41 to generate an electric field inside the semiconductor substrate 41. Note that besides the P+ semiconductor regions 773, the P− semiconductor regions 774 in which the concentration of acceptor impurities is low may also be recognized as the voltage application units.

On the interface on the front surface side of the semiconductor substrate 41 that is a side on which the multilayer interconnection layer 42 is formed, a diffusion film 811 regularly arranged at a prescribed interval is, for example, arranged. Further, although omitted in the figure, an insulating film (gate insulating film) is formed between the diffusion film 811 and the interface of the semiconductor substrate 41.

The diffusion film 811 is similar to the diffusion film 419 formed in the pixel 10 of FIG. 30 or the like. That is, the diffusion film 811 is regularly arranged at, for example, a prescribed interval on the interface on the front surface side of the semiconductor substrate 41 that is a side on which the multilayer interconnection layer 42 is formed, and light that penetrates to the multilayer interconnection layer 42 from the semiconductor substrate 41 and light reflected by a reflection member 815 that will be described later are diffused by the diffusion film 811 to be prevented from further penetrating to the outside (the side of the on-chip lens 47) of the semiconductor substrate 41. The diffusion film 811 may also be made of a material such as polysilicon having polycrystalline silicon as its main ingredient.

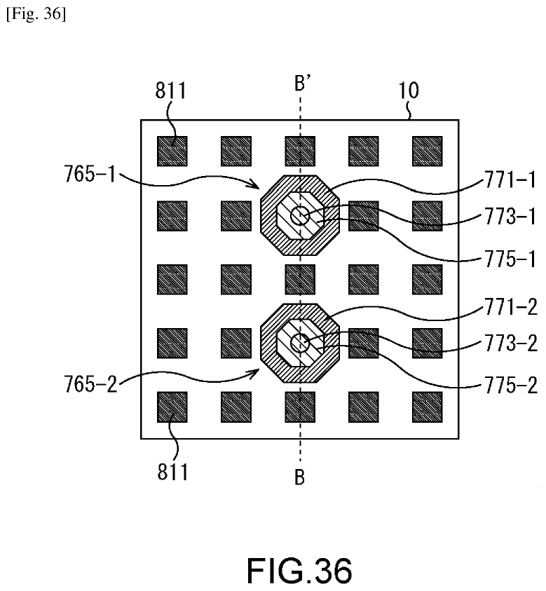

Note that as shown in FIG. 36, the diffusion film 811 is formed to avoid the positions of the N+ semiconductor region 771-1 and the P+ semiconductor region 773-1 so as not to overlap the positions of the N+ semiconductor region 771-1 and the P+ semiconductor region 773-1.

In FIG. 35, a first metal film M1 closest to the semiconductor substrate 41 among the first metal film M1 to a fifth metal film M5 of the multilayer interconnection layer 42 includes a power supply line 813 that supplies a power supply voltage, a voltage application interconnection 814 that applies a prescribed voltage to the P+ semiconductor region 773-1 or 773-2, and a reflection member 815 that is a member to reflect incident light. The voltage application interconnection 814 is connected to the P+ semiconductor region 773-1 or 773-2 via a contact electrode 812 and applies a prescribed voltage MIX0 and a prescribed voltage MIX1 to the P+ semiconductor region 773-1 and the P+ semiconductor region 773-2, respectively.

In the first metal film M1 of FIG. 35, an interconnection other than the power supply line 813 and the voltage application interconnection 814 becomes the reflection member 815, but some reference symbols are omitted to prevent the complication of the drawing. The reflection member 815 is a dummy interconnection provided to reflect incident light. The reflection member 815 is arranged under the N+ semiconductor regions 771-1 and 771-2 so as to overlap the N+ semiconductor regions 771-1 and 771-2 that are charge detection units in a plan view. Further, in the first metal film M1, a contact electrode (not shown) that connects the N+ semiconductor regions 771 and the transfer transistors 721 to each other is also formed to transfer charges accumulated in the N+ semiconductor regions 771 to the FDs 722.

Note that the reflection member 815 is arranged in the same layer of the first metal film M1 in this example but is not necessarily arranged in the same layer.

In the second metal film M2 that is the second layer from the side of the semiconductor substrate 41, a voltage application interconnection 816 that is connected to the voltage application interconnection 814 of the first metal film M1, a control line 817 that transmits the transfer drive signal TRG, the reset drive signal RST, the selection drive signal SEL, the FD drive signal FDG, or the like, a ground line, or the like is, for example, formed. Further, the FDs 722 or the like are also formed in the second metal film M2.

In the third metal film M3 that is the third layer from the side of the semiconductor substrate 41, the vertical signal line 29, an interconnection for shielding, or the like is, for example, formed.

In the fourth metal film M4 that is the fourth layer from the side of the semiconductor substrate 41, a voltage supply line (not shown) that applies a prescribed voltage MIX0 or MIX1 to the P+ semiconductor regions 773-1 and 773-2 that are the voltage application units of the signal extraction units 765 is, for example, formed.

The operation of the pixel 10 of FIG. 35 that is a CAPD pixel will be described.

The vertical drive unit 22 drives the pixel 10 and distributes signals corresponding to charges obtained by photoelectric conversion to the FD 722A and the FD 722B (FIG. 34).

The vertical drive unit 22 applies a voltage to the two P+ semiconductor regions 773 via the contact electrode 812 or the like. For example, the vertical drive unit 22 applies a voltage of 1.5 V to the P+ semiconductor region 773-1 and applies a voltage of 0 V to the P+ semiconductor region 773-2.

Then, an electric field is generated between the two P+ semiconductor regions 773 in the semiconductor substrate 41, and a current flows from the P+ semiconductor region 773-1 to the P+ semiconductor region 773-2. In this case, holes move in the direction of the P+ semiconductor region 773-1 and electrons move in the direction of the P+ semiconductor region 773-1 inside the semiconductor substrate 41.

Accordingly, in such a state, when infrared light (reflected light) from the outside is incident on the semiconductor substrate 41 via the on-chip lens 47 and then photoelectrically converted into pairs of electrons and holes inside the semiconductor substrate 41, the obtained electrons are guided in the direction of the P+ semiconductor region 773-1 by the electric field between the P+ semiconductor regions 773 and moved into the N+ semiconductor region 771-1.

In this case, the electrons generated by the photoelectric conversion are used as signal carriers for detecting a signal corresponding to the amount of the infrared light incident on the pixel 10, that is, the amount of the received infrared light.

Thus, charges corresponding to the electrons moved into the N+ semiconductor region 771-1 are accumulated in the N+ semiconductor region 771-1 and detected by the column processing unit 23 via the FD 722A, the amplification transistor 724A, the vertical signal line 29A, or the like.

That is, the accumulated charges of the N+ semiconductor region 771-1 are transferred to the FD 722A directly connected to the N+ semiconductor region 771-1, and a signal corresponding the charges transferred to the FD 722A is read by the column processing unit 23 via the amplification transistor 724A or the vertical signal line 29A. Then, processing such as AD conversion processing is applied to the read signal by the column processing unit 23, and a pixel signal obtained as a result of the processing is supplied to the signal processing unit 26.

The pixel signal becomes a signal indicating the amount of the charges corresponding to the electrons detected by the N+ semiconductor region 771-1, that is, the amount of the charges accumulated in the FD 722A. In other words, the pixel signal can also be called a signal indicating the amount of the infrared light received by the pixel 10.

Note that like the case of the N+ semiconductor region 771-1, a pixel signal corresponding to electrons detected by the N+ semiconductor region 771-2 may also appropriately be used in distance measurement.

Further, at a next timing, a voltage is applied by the vertical drive unit 22 to the two P+ semiconductor regions 773 via the contact electrode 812 or the like so that an electric field is generated in a direction opposite to that of the electric field having been generated inside the semiconductor substrate 41 until that time. Specifically, for example, a voltage of 1.5 V is applied to the P+ semiconductor region 773-2, and a voltage of 0 V is applied to the P+ semiconductor region 773-1.

Thus, an electric field is generated between the two P+ semiconductor regions 773 in the semiconductor substrate 41, and a current flows from the P+ semiconductor region 773-2 to the P+ semiconductor region 773-1.

In such a state, when infrared light (reflected light) from the outside is incident on the semiconductor substrate 41 via the on-chip lens 47 and then photoelectrically converted into pairs of electrons and holes inside the semiconductor substrate 41, the obtained electrons are guided in the direction of the P+ semiconductor region 773-2 by the electric field between the P+ semiconductor regions 773 and moved into the N+ semiconductor region 771-2.

Thus, charges corresponding to the electrons moved into the N+ semiconductor region 771-2 are accumulated in the N+ semiconductor region 771-2 and detected by the column processing unit 23 via the FD 722B, the amplification transistor 724B, the vertical signal line 29B, or the like.

That is, the accumulated charges of the N+ semiconductor region 771-2 are transferred to the FD 722B directly connected to the N+ semiconductor region 771-2, and a signal corresponding the charges transferred to the FD 722B is read by the column processing unit 23 via the amplification transistor 724B or the vertical signal line 29B. Then, processing such as AD conversion processing is applied to the read signal by the column processing unit 23, and a pixel signal obtained as a result of the processing is supplied to the signal processing unit 26.

Note that like the case of the N+ semiconductor region 771-2, a pixel signal corresponding to electrons detected by the N+ semiconductor region 771-1 may also appropriately be used in distance measurement.

When pixel signals obtained by photoelectric conversion in periods different from each other in the same pixel 10 are obtained in the manner described above, the signal processing unit 26 can calculate a distance to a target object on the basis of the pixel signals.

FIG. 36 is a plan view showing the arrangement of the signal extraction units 765 and the diffusion film 811 in a case in which the pixel 10 is a CAPD pixel.

Like the diffusion film 351 shown in FIG. 27, the diffusion film 811 is configured in such a manner that rectangular protrusion portions are arranged at a prescribed interval. The diffusion film 811 is formed to avoid the positions of the N+ semiconductor regions 771, the P+ semiconductor regions 773, and the isolation portions 775 so as not to overlap the positions of the signal extraction units 765.

In the configuration example of the CAPD pixel configured as described above as well, the diffusion film 811 is formed on the interface on the front surface side of the semiconductor substrate 41 that is a side on which the multilayer interconnection layer 42 is formed. Since the diffusion film 811 is formed on the interface on the front surface of the semiconductor substrate 41, light that penetrates to the multilayer interconnection layer 42 from the semiconductor substrate 41 and light reflected by the reflection member 815 are diffused by the diffusion film 811. Thus, incident light which has been temporarily incident on the semiconductor substrate 41 is prevented from penetrating to the side of the on-chip lens 47 of the semiconductor substrate 41.

Accordingly, it is possible to confine incident light, which has been temporarily incident on the semiconductor substrate 41 from the side of the on-chip lens 47, inside the semiconductor substrate 41 with high efficiency according to the configuration example of the CAPD pixel of FIGS. 35 and 36. That is, it is possible to further increase the amount of infrared light photoelectrically converted inside the semiconductor substrate 41 and improve quantum efficiency (QE), that is, sensitivity to the infrared light. Note that the reflection member 815 can be omitted when light is satisfactorily reflected and diffused to the semiconductor substrate 41 by the diffusion film 811.

<21. Configuration Example of RGBIR Imaging Sensor>

The first to fourth configuration examples of the IR imaging sensor described above are not limited to light-receiving elements that receive only infrared light but can also be applied to RGBIR imaging sensors that receive infrared light and RGB light.

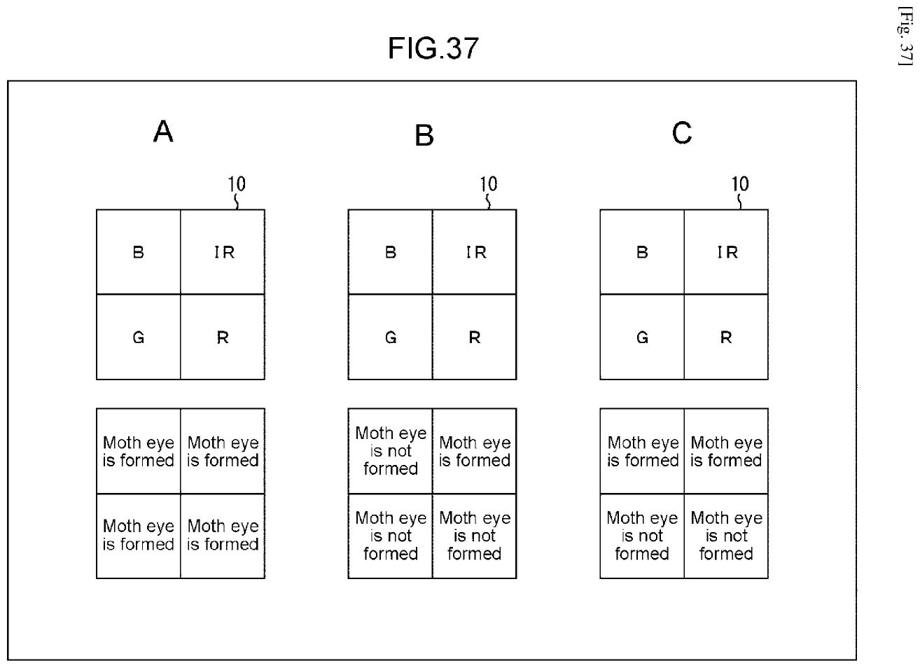

FIGS. 37A to 37C show a pixel arrangement example in a case in which the light-receiving element 1 includes an RGBIR imaging sensor that receives infrared light and RGB light.

In case in which the light-receiving element 1 includes an RGBIR imaging sensor, an R-pixel that receives the light of R (red), a B-pixel that receives the light of B (blue), a G-pixel that receives the light of G (green), and an IR-pixel that receives the light of IR (infrared) are allocated to four (2×2) pixels as shown in FIGS. 37A to 37C.

The respective pixels 10 have trench portions such as the interpixel trench portion 61, the in-pixel trench portion 112, and the interpixel trench portion 121 described above. However, three methods shown in FIGS. 37A to 37C can be employed as to whether a moth-eye structure in which fine irregularities are periodically formed is formed over the forming region of the photodiode PD.

FIG. 37A shows a configuration in which the moth-eye structure is formed in all the pixels 10 of the R-pixel, the B-pixel, the G-pixel, and the IR-pixel.

FIG. 37B shows a configuration in which the moth-eye structure is formed only in the IR-pixel and is not formed in the R-pixel, the B-pixel, and the G-pixel.

FIG. 37C shows a configuration in which the moth-eye structure is formed only in the B-pixel and the IR-pixel and is not formed in the R-pixel and the G-pixel. The pixel 10 in which the moth-eye structure is formed can reduce the reflection of the incident surface of the semiconductor substrate 41 and thus can improve its sensitivity. Note that the moth-eye structure may have a shape like the moth-eye structure portion 111 or a shape like the moth-eye structure portion 114.

<22. Configuration Example of Distance Measurement Module>

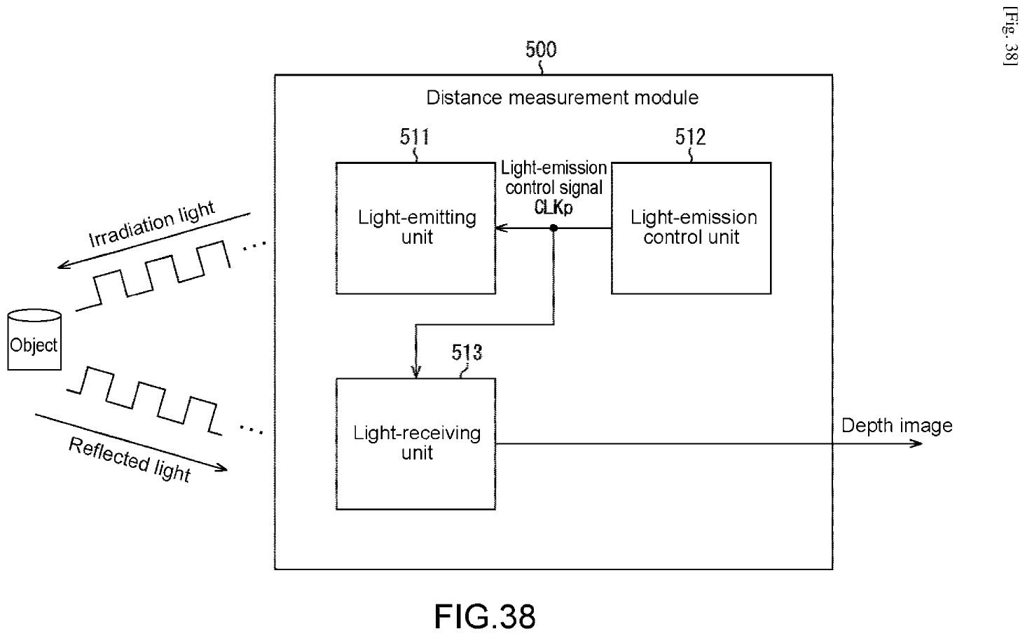

FIG. 38 is a block diagram showing a configuration example of a distance measurement module that outputs distance measurement information using the light-receiving element 1 described above.

A distance measurement module 500 includes a light-emitting unit 511, a light-emission control unit 512, and a light-receiving unit 513.

The light-emitting unit 511 has a light source that emits light having a prescribed wavelength, and emits irradiation light of which the brightness periodically fluctuates to irradiate an object with the irradiation light. For example, the light-emitting unit 511 has a light-emitting diode that emits infrared light having a wavelength of 780 nm to 1000 nm as a light source, and emits irradiation light in synchronization with a light-emission control signal CLKp having a rectangular wave that is supplied from the light-emission control unit 512.

Note that the light-emission control signal CLKp is not limited to a rectangular wave so long as the light-emission control signal CLKp is a periodic signal. For example, the light-emission control signal CLKp may have a sine wave.

The light-emission control unit 512 supplies the light-emission control signal CLKp to the light-emitting unit 511 and the light-receiving unit 513 and controls an irradiation timing of irradiation light. The light-emission control signal CLKp has a frequency of, for example, 20 megahertz (MHz). Note that the frequency of the light-emission control signal CLKp is not limited to 20 megahertz but may be 5 megahertz, 100 megahertz, or the like.

The light-receiving unit 513 receives reflected light reflected by an object, calculates distance information for each pixel according to a result of the light reception, and generates and outputs a depth image in which a depth value corresponding to a distance to the object (subject) is stored as a pixel value.

As the light-receiving unit 513, the light-receiving element 1 having the pixel structure of any of the first to seventh configuration examples based on the indirect ToF method, the first to third configuration examples of the SPAD pixel, and the configuration example of the CAPD pixel described above is used. For example, the light-receiving element 1 serving as the light-receiving unit 513 calculates distance information for each pixel from a detection signal corresponding to charges distributed to the floating diffusion region FD1 or FD2 of the respective pixels 10 of the pixel array unit 21 on the basis of the light-emission control signal CLKp.

As described above, the light-receiving element 1 having the pixel structure of any of the first to seventh configuration examples based on the indirect ToF method, the first to third configuration examples of the SPAD pixel, and the configuration example of the CAPD pixel described above can be embedded as the light-receiving unit 513 of the distance measurement module 500 that calculates and outputs information on a distance to a subject. Thus, it is possible to improve distance measurement characteristics as the distance measurement module 500.

<23. Configuration Example of Electronic Apparatus>

Note that the light-receiving element 1 is applicable to, for example, various electronic apparatuses such as imaging devices like digital still cameras or digital video cameras having a distance measurement function and smart phones having a distance measurement function, besides being applicable to distance measurement modules as described above.

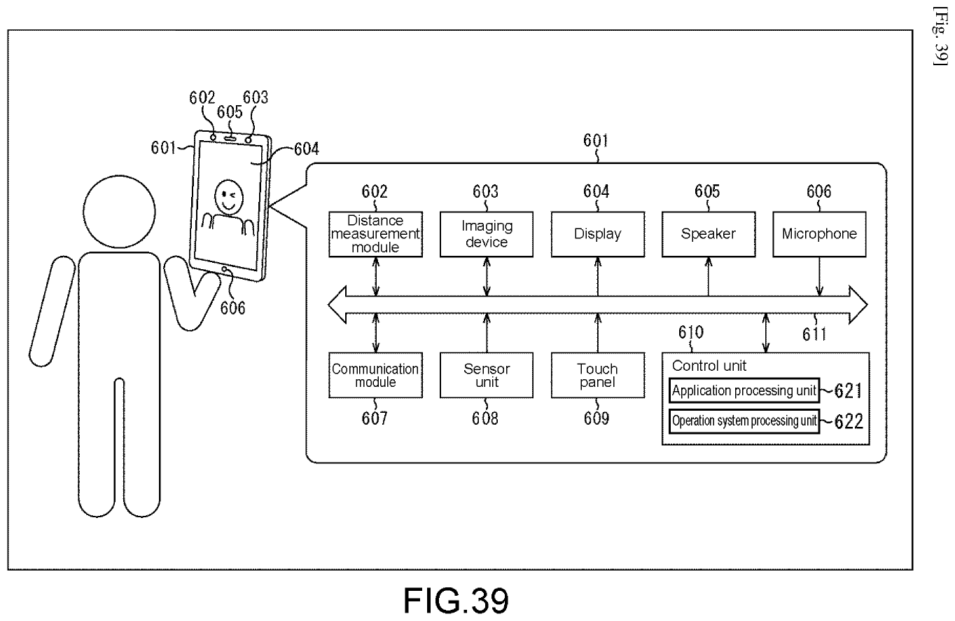

FIG. 39 is a block diagram showing a configuration example of a smart phone as an electronic apparatus to which the present technology is applied.

As shown in FIG. 39, a smart phone 601 is configured in such a manner that a distance measurement module 602, an imaging device 603, a display 604, a speaker 605, a microphone 606, a communication module 607, a sensor unit 608, a touch panel 609, and a control unit 610 are connected to each other via a bus 611. Further, the control unit 610 has functions as an application processing unit 621 and an operation system processing unit 622 when a CPU performs a program.

As the distance measurement module 602, the distance measurement module 500 of FIG. 38 is applied. For example, the distance measurement module 602 is arranged at the front of the smart phone 601. By performing distance measurement for a user of the smart phone 601, the distance measurement module 602 can output a depth value of the front surface shape of the face, the hand, the finger, or the like of the user as a distance measurement result.

The imaging device 603 is arranged at the front of the smart phone 601. By imaging the user of the smart phone 601 as a subject, the imaging device 603 acquires an image of the user. Note that although not shown in the figure, the imaging device 603 may also be arranged at the back of the smart phone 601.

The display 604 displays an operation screen to perform processing by the application processing unit 621 and the operation system processing unit 622, an image imaged by the imaging device 603, or the like. The speaker 605 and the microphone 606 perform the output of the voice of the other party and the collection of the voice of the user, for example, when a phone call is made using the smart phone 601.

The communication module 607 performs network communication via a communication network such as the Internet, a public telephone line network, a wide-range communication network such as so-called a 4-G line and a 5-G line for wireless mobile bodies, a WAN (Wide Area Network), and a LAN (Local Area Network), short-range wireless communication such as Bluetooth™ and NFC (Near Field Communication), or the like. The sensor unit 608 senses speed, acceleration, proximity, or the like, and the touch panel 609 acquires a touch operation performed by the user on an operation screen displayed on the display 604.

The application processing unit 621 performs processing to offer various services with the smart phone 601. For example, the application processing unit 621 can perform processing to generate a face based on computer graphics in which the facial expressions of the user are virtually reproduced and display the generated face on the display 604 on the basis of a depth value supplied from the distance measurement module 602. Further, the application processing unit 621 can perform, for example, processing to generate the three-dimensional shape data of any polygonal object on the basis of a depth value supplied from the distance measurement module 602.

The operation system processing unit 622 performs processing to realize the basic functions and operations of the smart phone 601. For example, the operation system processing unit 622 can perform processing to authenticate the face of the user and unlock the smart phone 601 on the basis of a depth value supplied from the distance measurement module 602. Further, the operation system processing unit 622 can perform, for example, processing to recognize a gesture of the user and input various operations according to the gesture on the basis of a depth value supplied from the distance measurement module 602.

In the smart phone 601 configured as described above, it is possible to perform, for example, processing to measure and display a distance to a prescribed object, processing to generate and display the three-dimensional shape data of a prescribed object, or the like with the application of the distance measurement module 500 described above as the distance measurement module 602.

<24. Application Example to Moving Body>

The technology (present technology) according to the present disclosure can be applied to various products. For example, the technology according to the present disclosure may be realized as a device mounted in any type of a moving body such as an automobile, an electric vehicle, a hybrid electric vehicle, an automatic two-wheeled vehicle, a bike, a personal mobility, an airplane, a drone, a ship, and a robot.

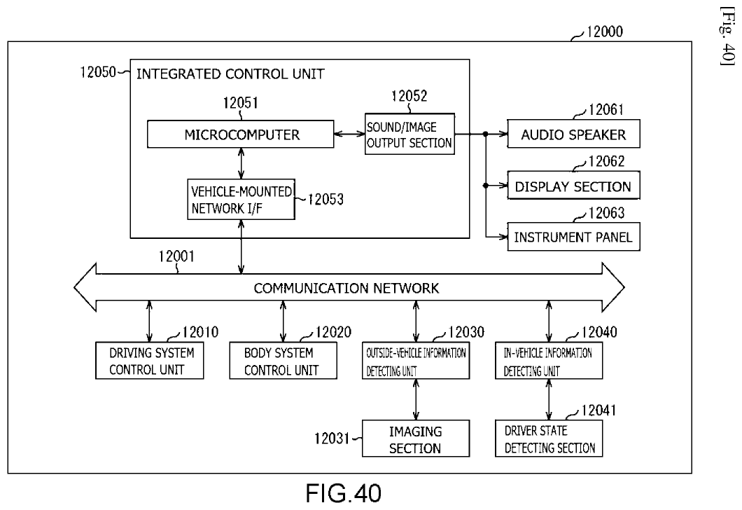

FIG. 40 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 40, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 40, an audio speaker 12061, a display section 12062, and an instrument panel 12063 are illustrated as the output device. The display section 12062 may, for example, include at least one of an on-board display and a head-up display.

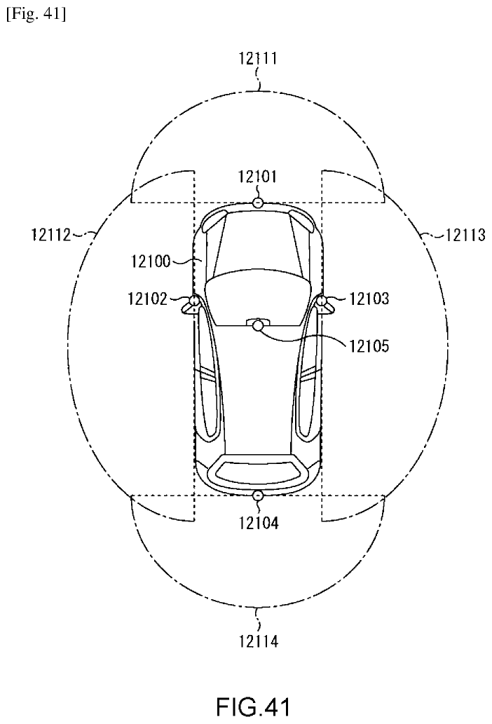

FIG. 41 is a diagram depicting an example of the installation position of the imaging section 12031.

In FIG. 41, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 41 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied has been described above. The technology according to the embodiment of the present disclosure can be applied to the outside-vehicle information detecting unit 12030 or the imaging section 12031 among the above-mentioned configurations. Specifically, the light-receiving element 1 or the distance measurement module 500 can be applied to the distance detection processing block of the outside-vehicle information detecting unit 12030 or the imaging section 12031. By applying the technology according to the embodiment of the present disclosure to the outside-vehicle information detecting unit 12030 or the imaging section 12031, it is possible to measure the distance to an object such as a human, a vehicle, an obstacle, a sign, a character on a road surface, or the like with high accuracy, and reduce driver fatigue and enhance the degree of safety of the driver and the vehicle by using the obtained distance information.

The embodiments of the present technology are not limited to the embodiments described above but can be modified in various ways without departing from the spirit of the present technology.

Further, an example in which electrons are used as signal carriers is described in the light-receiving element 1 described above, but holes generated by photoelectric conversion may be used as signal carriers.

For example, a mode in which all or some of the respective embodiments are combined with each other may be employed in the light-receiving element 1 described above.

Note that the effects described in the present specification are given only for illustration and are not interpreted in a limited way. Effects other than those described in the present specification may be produced.

Note that the present technology can employ the following configurations.

(1)

A light-receiving element including:

an on-chip lens;

an interconnection layer; and

a semiconductor layer arranged between the on-chip lens and the interconnection layer,

the semiconductor layer including

a photodiode,

an interpixel trench portion engraved up to at least a part in a depth direction of the semiconductor layer at a boundary portion of an adjacent pixel, and

an in-pixel trench portion engraved at a prescribed depth from a front surface or a rear surface of the semiconductor layer at a position overlapping a part of the photodiode in a plan view.

(2)

The light-receiving element according to (1), in which

the semiconductor layer further includes

a first transfer transistor that transfers charges generated by the photodiode to a first charge accumulation unit,

a second transfer transistor that transfers the charges generated by the photodiode to a second charge accumulation unit, and

the first charge accumulation unit and the second charge accumulation unit.

(3)

The light-receiving element according to (1), in which

the semiconductor layer further includes

a transfer transistor that transfers charges generated by the photodiode to a charge accumulation unit and

the charge accumulation unit.

(4)

The light-receiving element according to any of (1) to (3), in which

the interpixel trench portion is engraved to such an extent as to penetrate the semiconductor layer.

(5)

The light-receiving element according to any of (1) to (4), in which

the in-pixel trench portion is engraved at a prescribed depth from the rear surface of the semiconductor layer on which the on-chip lens is formed.

(6)

The light-receiving element according to any of (1) to (4), in which

the in-pixel trench portion is engraved at a prescribed depth from the front surface of the semiconductor layer on which the interconnection layer is formed.

(7)

The light-receiving element according to any of (1) to (6), in which

the in-pixel trench portion is arranged so that a rectangular planar region of the pixel is divided into a plurality of regions in each of a horizontal direction and a vertical direction in a plan view.

(8)

The light-receiving element according to any of (1) to (7), in which

the in-pixel trench portion is formed into a cross shape in which a rectangular planar region of the pixel is divided into four regions in a plan view.

(9)

The light-receiving element according to (8), in which

the in-pixel trench portion is not formed at an intersection thereof having the cross shape.

(10)

The light-receiving element according to any of (1) to (9), in which

an irregularity structure having periodicity is formed on a rear surface side of the semiconductor layer on which the on-chip lens is formed.

(11)

The light-receiving element according to (10), in which

the in-pixel trench portion is formed in a recessed portion of the irregularity structure having the periodicity.

(12)

The light-receiving element according to any of (1) to (11), in which

the in-pixel trench portion and the interpixel trench portion are made of the same material.

(13)

The light-receiving element according to any of (1) to (11), in which

the in-pixel trench portion and the interpixel trench portion are made of different materials.

(14)

The light-receiving element according to any of (1) to (13), in which

the one on-chip lens is formed on an upper surface of the semiconductor layer on a light incident surface side of the one photodiode.

(15)

The light-receiving element according to any of (1) to (13), in which

a plurality of the on-chip lenses is formed on an upper surface of the semiconductor layer on a light incident surface side of the one photodiode.

(16)

The light-receiving element according to (15), in which

four pieces of the on-chip lenses are formed on the upper surface of the semiconductor layer on the light incident surface side of the one photodiode.

(17)

The light-receiving element according to any of (1) to (16), in which

the interconnection layer has at least one layer including a light-shielding member, and

the light-shielding member is provided so as to overlap the photodiode in a plan view.

(18)

The light-receiving element according to any of (1) to (17), in which

the interconnection layer has a diffusion film regularly arranged at a prescribed interval on an interface on a front surface side of the semiconductor layer.

(19)

A distance measurement module including:

a prescribed light-emitting source; and

a light-receiving element,

the light-receiving element including

an on-chip lens,

an interconnection layer, and

a semiconductor layer arranged between the on-chip lens and the interconnection layer,

the semiconductor layer including

a photodiode,

an interpixel trench portion engraved up to at least a part in a depth direction of the semiconductor layer at a boundary portion of an adjacent pixel, and

an in-pixel trench portion engraved at a prescribed depth from a front surface or a rear surface of the semiconductor layer at a position overlapping a part of the photodiode in a plan view.

(20)

An electronic apparatus including:

a distance measurement module including

a prescribed light-emitting source and

a light-receiving element,

the light-receiving element including

an on-chip lens,

an interconnection layer, and

a semiconductor layer arranged between the on-chip lens and the interconnection layer, the semiconductor layer including

a photodiode,

an interpixel trench portion engraved up to at least a part in a depth direction of the semiconductor layer at a boundary portion of an adjacent pixel, and

an in-pixel trench portion engraved at a prescribed depth from a front surface or a rear surface of the semiconductor layer at a position overlapping a part of the photodiode in a plan view.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 light-receiving element
10 pixel
21 pixel array unit
41 semiconductor substrate
44 boundary portion (pixel boundary portion)
47 on-chip lens
61 interpixel trench portion
62 interlayer insulating film
63 light-shielding member
111 moth-eye structure portion
112 in-pixel trench portion
121 interpixel trench portion
141 in-pixel trench portion
161 on-chip lens
351 diffusion film
419 diffusion film
451 diffusion film
500 distance measurement module
513 light-receiving unit
811 diffusion film

What is claimed is:

1-20. (canceled)

21. A light detecting device, comprising:
a photoelectric conversion element disposed in a semiconductor substrate, wherein the photoelectric conversion element is disposed between a first inter-pixel trench and a second inter-pixel trench adjacent to the first inter-pixel trench in a cross-sectional view;
a plurality of recess portions disposed between the first inter-pixel trench and the second inter-pixel trench in the cross-sectional view, wherein the plurality of recess portions are included a light receiving surface of the semiconductor substrate in the cross-sectional view; and
an on-chip lens disposed above the photoelectric conversion element, wherein the on-chip lens is disposed between the first inter-pixel trench and the second inter-pixel trench in the cross-sectional view,
wherein the plurality of recess portions include first to fifth recess portions extending in a vertical direction in a plan view, and
wherein the plurality of recess portions include sixth to tenth recess portions extending in a horizontal direction in the plan view.

22. The light detecting device according to claim 21, further comprising:
a first charge accumulation unit and a second charge accumulation unit configured to accumulates an electric charge transferred from the photoelectric conversion element.

23. The light detecting device according to claim 22, further comprising:
a first transfer transistor and a second transfer transistor configured to transfer the electric charge from the photoelectric conversion element.

24. The light detecting device according to claim 23,
wherein the first transfer transistor is configured to transfer the electric charge to the first charge accumulation unit from the photoelectric conversion element, and
wherein the second transfer transistor is configured to transfer the first electric charge to the second charge accumulation unit from the photoelectric conversion element.

25. The light detecting device according to claim 21, wherein the semiconductor substrate is disposed between the on-chip lens and a wiring layer in the cross-sectional view.

26. The light detecting device according to claim 25, further comprising:
a light-shielding member disposed at the wiring layer in the cross-sectional view.

27. The light detecting device according to claim 26, wherein the light-shielding member includes metal.

28. The light detecting device according to claim 21, wherein the first to tenth recess portions do not contact an inter-pixel trench surrounding the photoelectric conversion element in the plan view.

29. The light detecting device according to claim 21, further comprising:
a first film disposed above the light receiving surface of the semiconductor substrate in the cross-sectional view.

30. The light detecting device according to claim 29, further comprising:
a second film disposed above the first film in the cross-sectional view.

31. The light detecting device according to claim 30, further comprising:
a third film disposed above the second film in the cross-sectional view.

32. The light detecting device according to claim 31, wherein the first film includes aluminum oxide.

33. The light detecting device according to claim 32, wherein the second film includes hafnium oxide.

34. The light detecting device according to claim 33, wherein the third film includes silicon oxide.

35. An electronic apparatus, comprising:
a pixel array unit, including:
a plurality of light detecting devices, each of the light detecting devices comprising:
a photoelectric conversion element disposed in a semiconductor substrate, wherein the photoelectric conversion element is disposed between a first inter-pixel trench and a second inter-pixel trench adjacent to the first inter-pixel trench in a cross-sectional view;
a plurality of recess portions disposed between the first inter-pixel trench and the second inter-pixel trench in the cross-sectional view, wherein the plurality of recess portions are included a light receiving surface of the semiconductor substrate in the cross-sectional view; and
an on-chip lens disposed above the photoelectric conversion element, wherein the on-chip lens is disposed between the first inter-pixel trench and the second inter-pixel trench in the cross-sectional view,
wherein the plurality of recess portions include first to fifth recess portions extending in a vertical direction in a plan view, and
wherein the plurality of recess portions include sixth to tenth recess portions extending in a horizontal direction in the plan view; and
a signal processing unit; and
a data storage unit.
